(19) United States
(12) Patent Application Publication
(10) Pub. No.: US 2026/0321312 A1
(43) Pub. Date: Oct. 15, 2026

(54) NON-VOLATILE MEMORY WITH PROCESS FRIENDLY CONTROL GATE DRIVERS

(71) Applicant: Sandisk Technologies, Inc., Milpitas, CA (US)

(72) Inventors: Hardwell Chibvongodze, Hiratsuka (JP); Alvin Joshua, Fujisawa (JP); Yuki Kuniyoshi, Fujisawa (JP); Akitomo Nakayama, Yokohama (JP)

(73) Assignee: Sandisk Technologies, Inc., Milpitas, CA (US)

(21) Appl. No.: 19/179,518

(22) Filed: Apr. 15, 2025

(51) Int. Cl. G11C 16/08; G11C 5/06; G11C 16/04; H10B 43/10; H10B 43/27; H10B 43/35; H10B 80/00; H10D 30/01; H10D 30/69; H10D 80/30; H10W 90/00; H10W 90/24

(52) U.S. Cl. CPC G11C 16/08; G11C 5/063; G11C 16/0483; H10B 43/10; H10B 43/27; H10B 43/35; H10D 30/0413; H10D 30/693; H10B 80/00; H10D 80/30; H10W 90/24; H10W 90/724; H10W 90/752; H10W 90/754; H10W 90/792

(57) ABSTRACT

To avoid design delays to control circuitry when the number of word lines of a 3D NAND array changes, in addition to a set of a fixed number of data word lines, a set of reserve word lines are included at locations such as the top or bottom of the word line stack that commonly undergo changes in word line numbers in the design phase. In addition to the unselected word line control gate drivers for the fixed set of word lines, the unselected word line control gate drivers for the reserved word lines can be configured based on the number reserve word lines included in the array design. This way, if the number of reserve word lines changes in the design process, the control circuitry does not to be redesigned, but just have the number of active unselected word line control gate drivers for the reserved word lines reconfigured.

### BACKGROUND

The present disclosure relates to non-volatile storage.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. A non-volatile memory allows information to be stored and retained even when the non-volatile memory is not connected to a source of power (e.g., a battery). Examples of non-volatile memory include flash memory (e.g., NAND-type and NOR-type flash memory).

Semiconductor memory devices are very complicated and complex to fabricate, often undergoing multiple design changes during the development process. These design changes can be very costly and time-consuming. This can particularly be the case for three-dimensional NAND flash memories, where word line layers are often added or removed during development and causing corresponding changes in the control circuitry to be made. Semiconductor memory device development would consequently greatly benefit if the design revision process could be speed up and made less expensive.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIGS. 3A and 3B depict different embodiments of integrated memory assemblies.

FIG. 4 is a perspective view of a portion of one embodiment of a monolithic three-dimensional memory structure.

FIG. 4A is a block diagram of one embodiment of a memory structure having two planes.

FIG. 4B depicts a top view of a portion of one embodiment of a block of memory cells.

FIG. 4C depicts a cross-sectional view of a portion of one embodiment of a block of memory cells.

FIG. 4D depicts a cross-sectional view of a portion of one embodiment of a block of memory cells.

FIG. 4E depicts a cross-sectional view of a portion of one embodiment of a block of memory cells.

FIG. 4F is a cross-sectional view of one embodiment of a vertical column of memory cells.

FIG. 4G depicts a cross section of a memory hole that implements a vertical NAND string.

FIG. 4H depicts a cross section of a memory hole that implements a vertical NAND string.

FIG. 4I depicts a cross section of a memory hole that implements a vertical NAND string.

FIG. 4J is a schematic of a plurality of NAND strings.

FIG. 5A depicts threshold voltage distributions.

FIG. 5B depicts threshold voltage distributions.

FIG. 5C depicts threshold voltage distributions.

FIG. 5D depicts threshold voltage distributions.

FIG. 5E depicts threshold voltage distributions.

FIG. 5F depicts threshold voltage distributions.

FIG. 6 is a flow chart describing one embodiment of a process for programming non-volatile memory.

FIG. 7 is a signal timing diagram describing one embodiment of the programming process.

FIG. 8 is a block diagram depicting a vertical column that spans two sub-blocks and has its diameter increase from bottom of the vertical column to top of the vertical column within the sub-blocks.

FIG. 9 illustrates an arrangement of control gate drivers for word lines in an example without the inclusion of the reserve word lines.

FIG. 10 illustrates an embodiment for the layout of control gate drivers incorporating reserve word lines.

FIG. 11 illustrates a further embodiment that further includes reserve word lines in the central region of a memory block.

FIG. 12 illustrates another embodiment that includes reserve word lines in the central region of a memory block.

FIG. 13 illustrates an embodiment for applying the use of reserve memory lines to a 3-tier example of a multi-tier memory hole process

FIG. 14 is a flowchart of an embodiment for forming the control circuitry presented with respect to FIGS. 10-13.

### DETAILED DESCRIPTION

The scaling of flash memory, such as three-dimension NAND memory, is achieved by increasing the number of word lines. The increasing height of the word line stack introduces greater processing complexity into the manufacturing process and it is common to change the number of word lines, either adding or deleting word lines. These changes are often made at the top or bottom end of the stack or at additional locations where critical dimension issues arise. When the number of word lines is changed, this will also require changes in the control circuitry, such as the number of drivers needed for the word lines unselected during a memory operation. Such changes in the control circuitry can be very time consuming, leading to development delays for memory devices.

To avoid such delays, embodiments presented below present a 3D NAND array that, in addition to a set of a fixed number of data word lines, has a set of reserve word lines at locations such as the top or bottom of the word line stack that commonly undergo changes in word line numbers in the design phase. In addition to the unselected word line control gate drivers for the fixed set of word lines, the unselected word line control gate drivers for the reserved word lines can be configured based on the number of reserve word lines included in the array design. This way, if the number of reserve word lines changes in the design process, the control circuitry does not need to be redesigned, but just have the number of active unselected word line control gate drivers for the reserved word lines reconfigured.

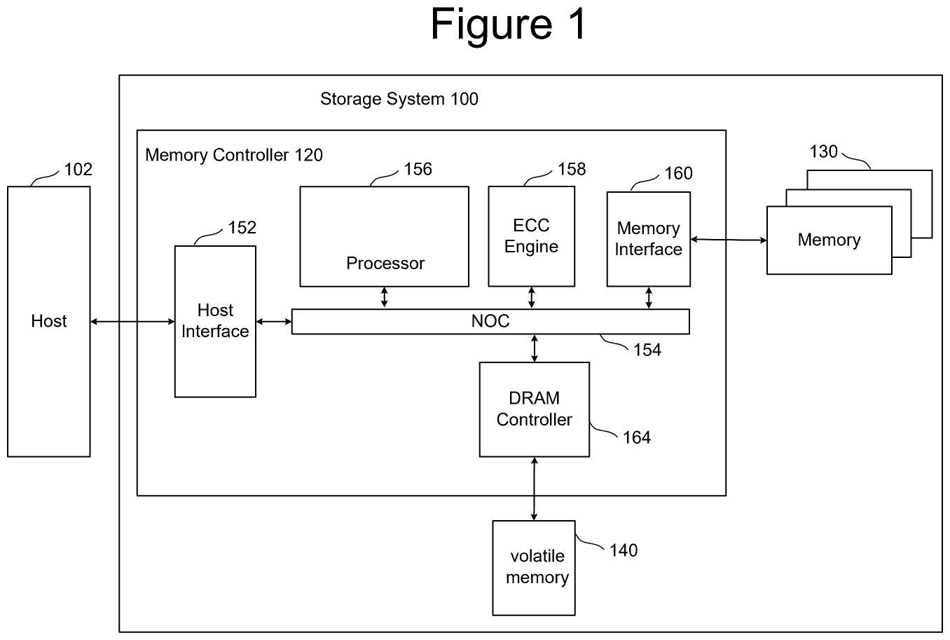

FIG. 1 is a block diagram of one embodiment of a non-volatile storage system 100 that implements the proposed technology described herein. In one embodiment, non-volatile storage system 100 is a solid-state drive (“SSD”). Non-volatile storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 connected to non-volatile memory 130 and local high speed volatile memory 140 (e.g., DRAM). Local high speed volatile memory 140 is used by memory controller 120 to perform certain functions. For example, local high speed volatile memory 140 stores logical to physical address translation tables (“L2P tables”).

Memory controller 120 comprises a host interface 152 that is connected to and in communication with host 102. In one embodiment, host interface 152 implements a NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keeps growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and DRAM controller 164. DRAM controller 164 is used to operate and communicate with local high speed volatile memory 140 (e.g., DRAM). In other embodiments, local high speed volatile memory 140 can be SRAM or another type of volatile memory.

ECC engine 158 performs error correction services. For example, ECC engine 158 performs data encoding and decoding, as per the implemented ECC technique. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory dies. One example implementation is to maintain tables (i.e. the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a memory die 130 and a subset of the L2P tables are cached (L2P cache) in the local high speed volatile memory 140.

Memory interface 160 communicates with non-volatile memory 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

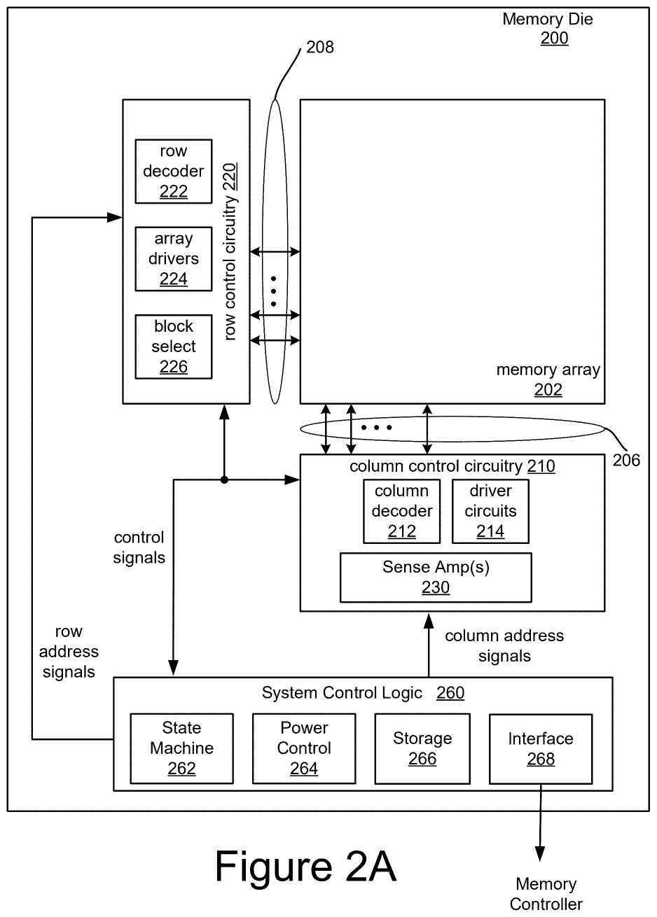

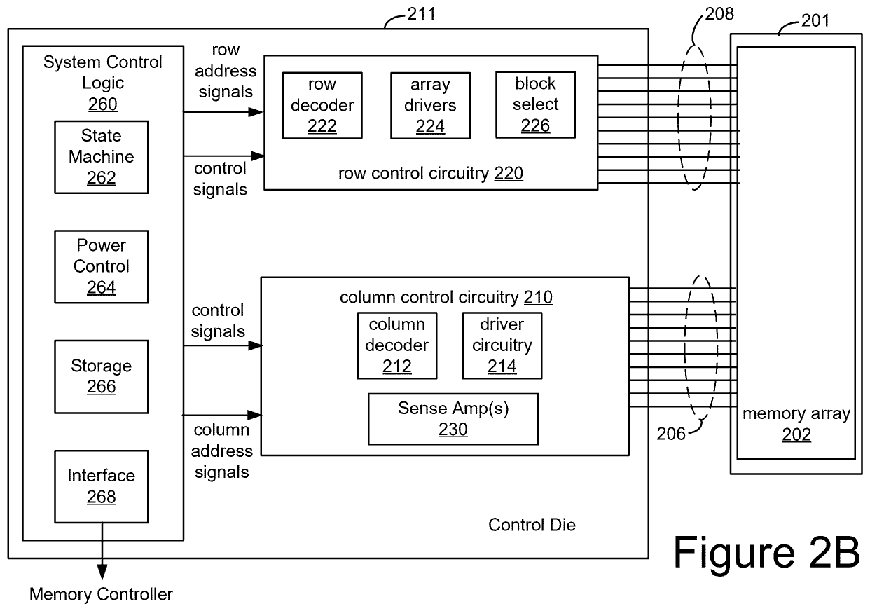

In one embodiment, non-volatile memory 130 comprises one or more memory die. FIG. 2A is a functional block diagram of one embodiment of a memory die 200 that comprises non-volatile memory 130. Each of the one or more memory die of non-volatile memory 130 can be implemented as memory die 200 of FIG. 2A. The components depicted in FIG. 2A are electrical circuits. Memory die 200 includes a memory array 202 that can comprise non-volatile memory cells, as described in more detail below. The array terminal lines of memory array 202 include the various layer(s) of word lines organized as rows, and the various layer(s) of bit lines organized as columns. However, other orientations can also be implemented. Memory die 200 includes row control circuitry 220, whose outputs 208 are connected to respective word lines of the memory array 202. Row control circuitry 220 receives a group of M row address signals and one or more various control signals from System Control Logic circuit 206, and typically may include such circuits as row decoders 222, array terminal drivers 224, and block select circuitry 226 for both reading and writing (programming) operations. Row control circuitry 220 may also include read/write circuitry. Memory die 200 also includes column control circuitry 210 including sense amplifier(s) 230 whose input/outputs 206 are connected to respective bit lines of the memory array 202. Although only single block is shown for array 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, as well as read/write circuitry, and I/O multiplexers.

System control logic 260 receives data and commands from memory controller 120 and provides output data and status to the host. In some embodiments, the system control logic 260 (which comprises one or more electrical circuits) include state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 262 can also include a power control module 264 that controls the power and voltages supplied to the rows and columns of the memory structure 202 during memory operations and may include charge pumps and regulator circuit for creating regulating voltages. System control logic 262 includes storage 366 (e.g., RAM, registers, latches, etc.), which may be used to store parameters for operating the memory array 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all the components depicted in FIG. 2A other than memory structure 202. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ CMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile memory 130 of storage system 100. The integrated memory assembly 207 includes two types of semiconductor die (or more succinctly, “die”). Memory die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory die 201. In some embodiments, the memory die 201 and the control die 211 are bonded together.

FIG. 2B shows an example of the peripheral circuitry, including control circuits, formed in a peripheral circuit or control die 211 coupled to memory structure 202 formed in memory die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory die 201. In some embodiments, some of the circuitry in the system control logic 260 is located on the on the memory die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory 2 die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including sense amplifier(s) 230 on the control die 211 coupled to memory structure 202 on the memory die 201 through electrical paths 206. For example, electrical paths 206 may provide electrical connection between column decoder 212 and driver circuitry 214, and bit lines of memory structure 202. Electrical paths may extend from column control circuitry 210 in control die 211 through pads on control die 211 that are bonded to corresponding pads of the memory die 201, which are connected to bit lines of memory structure 202. Each bit line of memory structure 202 may have a corresponding electrical path in electrical paths 306, including a pair of bond pads, which connects to column control circuitry 210. Similarly, row control circuitry 220, including row decoder 222, array drivers 224, and block select 226 are coupled to memory structure 202 through electrical paths 208. Each of electrical path 208 may correspond to a word line, dummy word line, or select gate line. Additional electrical paths may also be provided between control die 211 and memory die 201.

For purposes of this document, the phrases “a control circuit” or “one or more control circuits” can include any one of or any combination of memory controller 120, state machine 262, all or a portion of system control logic 260, all or a portion of row control circuitry 220, all or a portion of column control circuitry 210, a microcontroller, a microprocessor, and/or other similar functioned circuits. The control circuit can include hardware only or a combination of hardware and software (including firmware). For example, a controller programmed by firmware to perform the functions described herein is one example of a control circuit. A control circuit can include a processor, FGA, ASIC, integrated circuit, or other type of circuit.

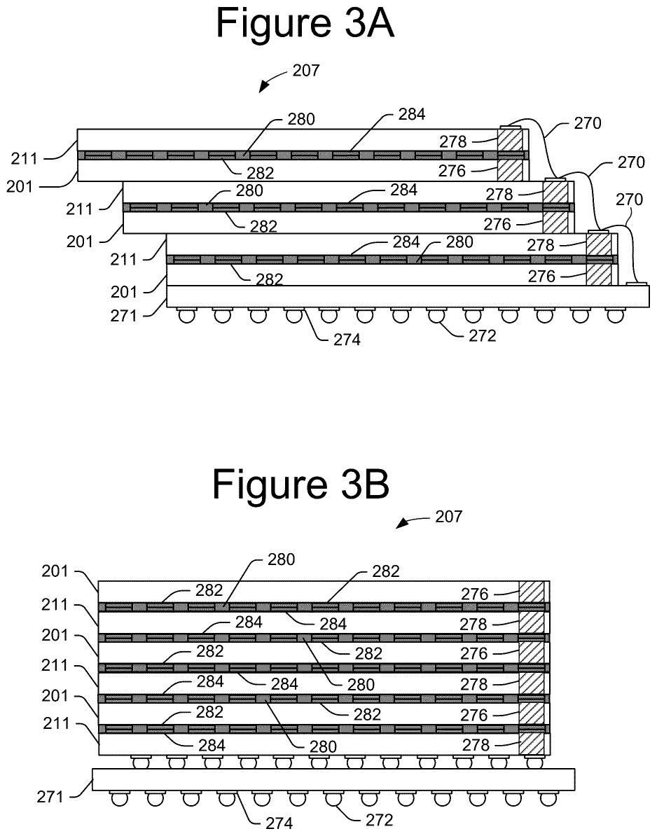

In some embodiments, there is more than one control die 211 and more than one memory die 201 in an integrated memory assembly 207. In some embodiments, the integrated memory assembly 207 includes a stack of multiple control die 211 and multiple memory die 201. FIG. 3A depicts a side view of an embodiment of an integrated memory assembly 207 stacked on a substrate 271 (e.g., a stack comprising control dies 211 and memory dies 201). The integrated memory assembly 207 has three control dies 211 and three memory dies 201. In some embodiments, there are more than three memory dies 201 and more than three control die 211.

Each control die 211 is affixed (e.g., bonded) to at least one of the memory dies 201. Some of the bond pads 282/284 are depicted. There may be many more bond pads. A space between two dies 201, 211 that are bonded together is filled with a solid layer 280, which may be formed from epoxy or other resin or polymer. This solid layer 280 protects the electrical connections between the dies 201, 211, and further secures the dies together. Various materials may be used as solid layer 280, but in embodiments, it may be Hysol epoxy resin from Henkel Corp., having offices in California, USA.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 3A).

A memory die through silicon via (TSV) 276 may be used to route signals through a memory die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control die 211 and three memory die 201. In some embodiments, there are many more than three memory dies 201 and many more than three control dies 211. In this example, each control die 211 is bonded to at least one memory die 201. Optionally, a control die 211 may be bonded to two or more memory die 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory die 201 may be bonded together. Bond pads on each die 201, 211 may be used to bond the two dies together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor dies including the bond pads. The film layer is provided around the bond pads. When the dies are brought together, the bond pads may bond to each other, and the film layers on the respective dies may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on the surface of the dies 201, 211. Where no such film is initially provided, a space between the dies may be under filled with an epoxy or other resin or polymer. The under-fill material may be applied as a liquid which then hardens into a solid layer. This under-fill step protects the electrical connections between the dies 201, 211, and further secures the dies together. Various materials may be used as under-fill material, but in embodiments, it may be Hysol epoxy resin from Henkel Corp., having offices in California, USA.

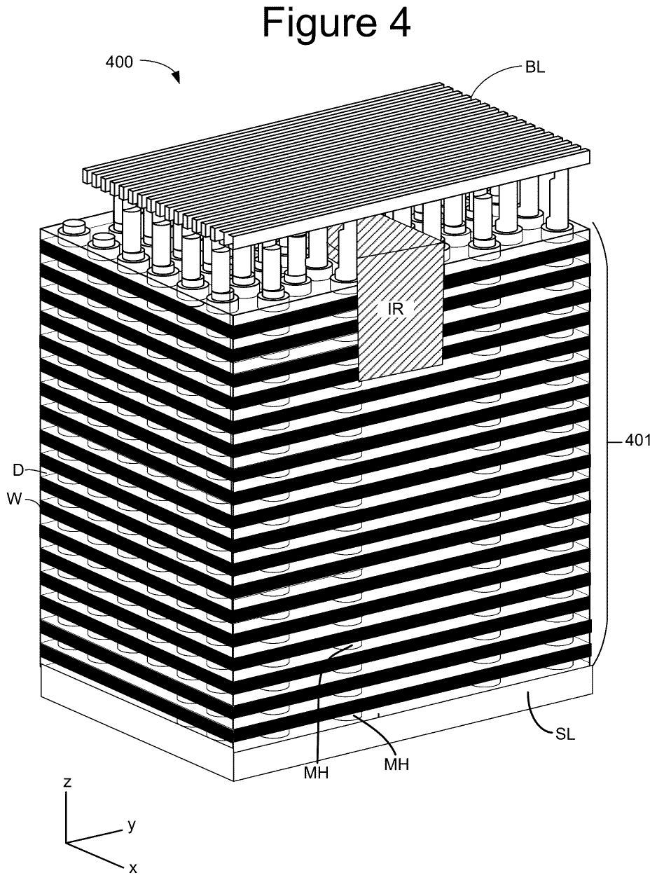

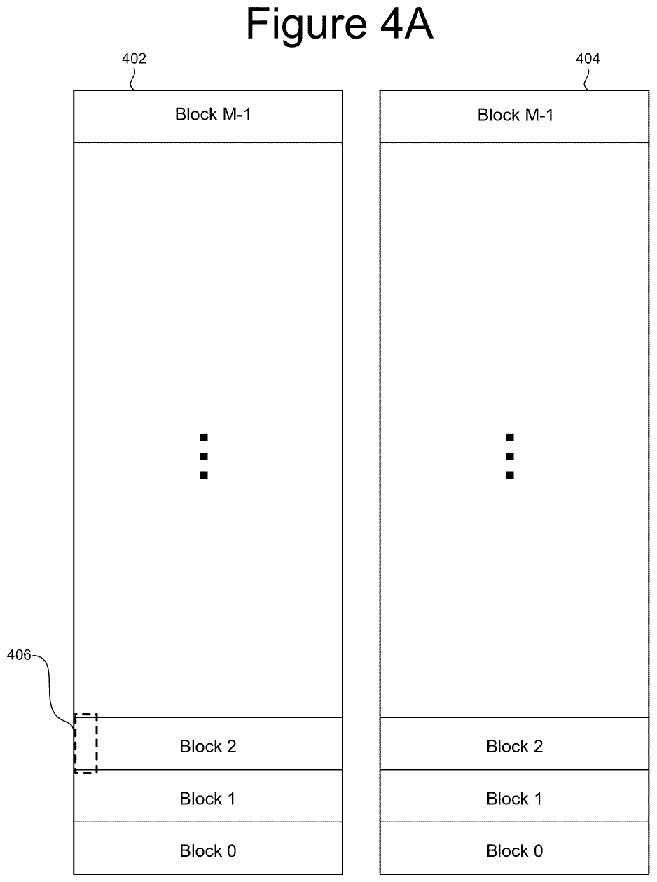

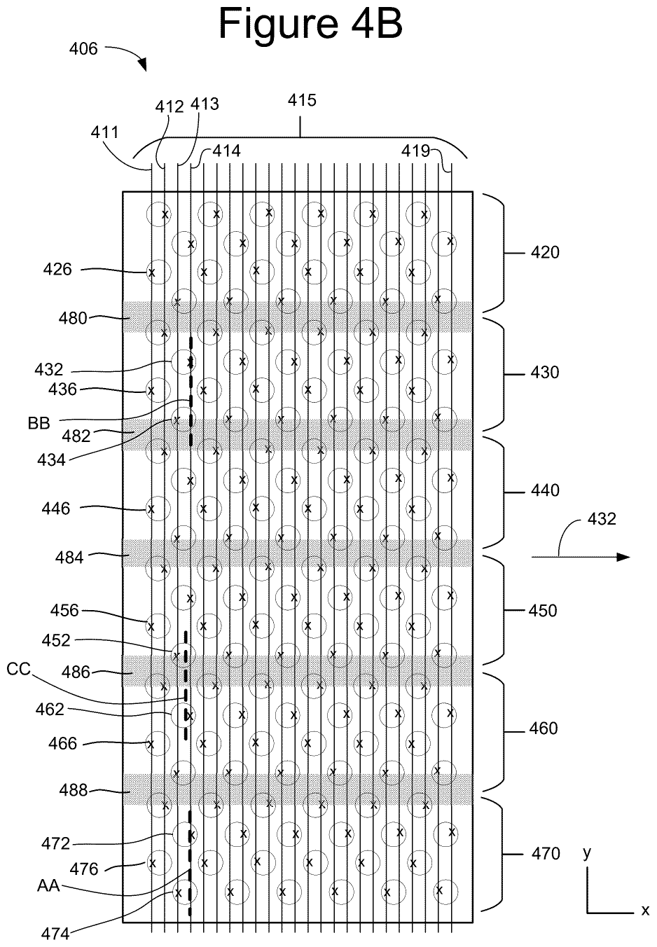

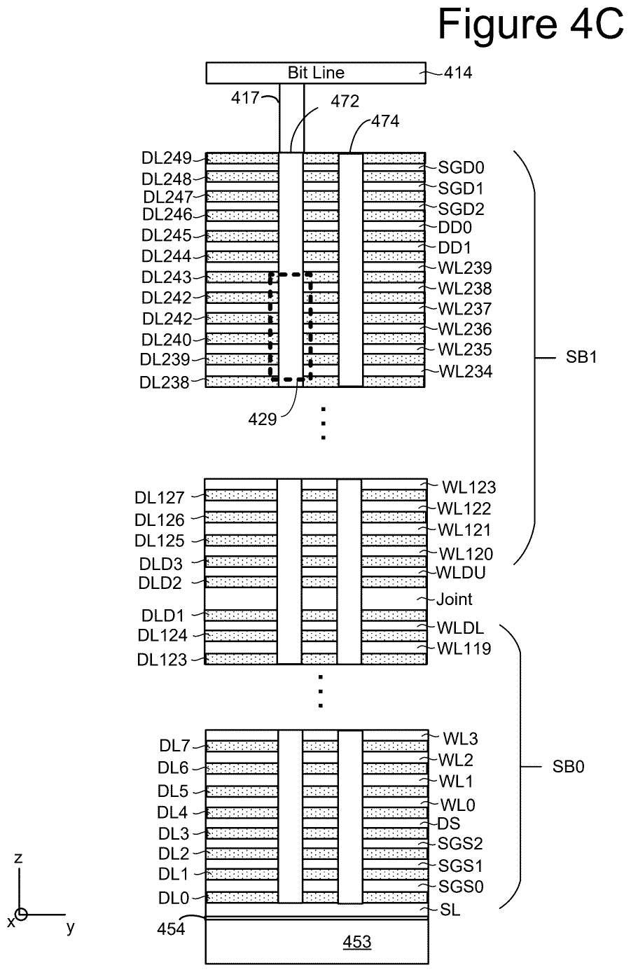

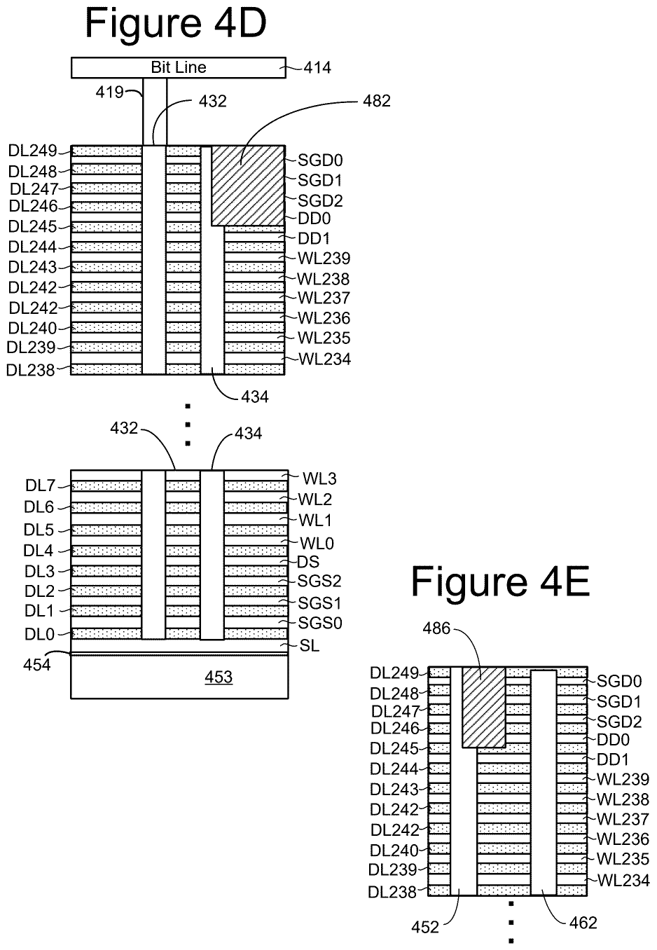

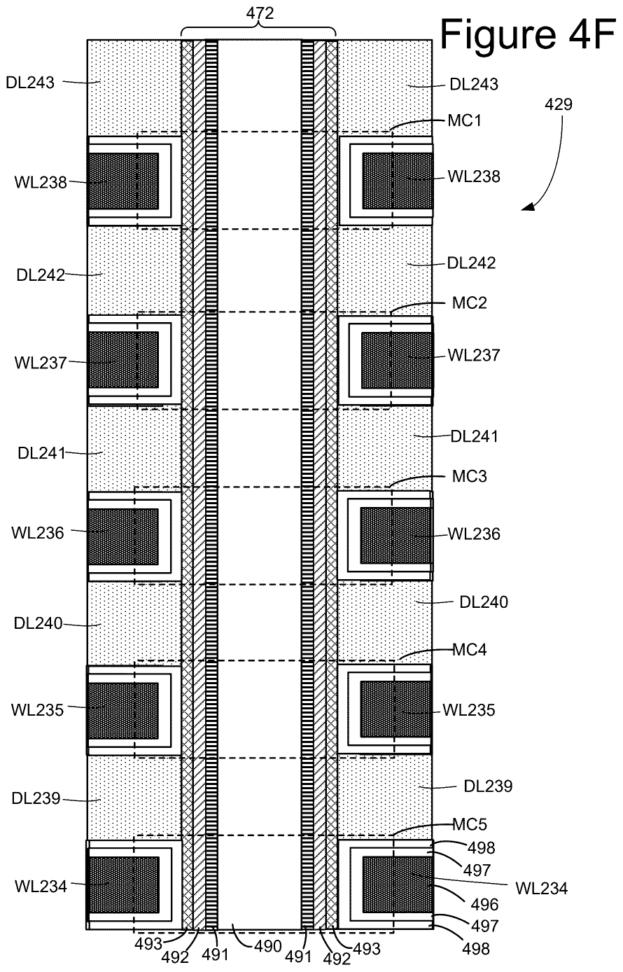

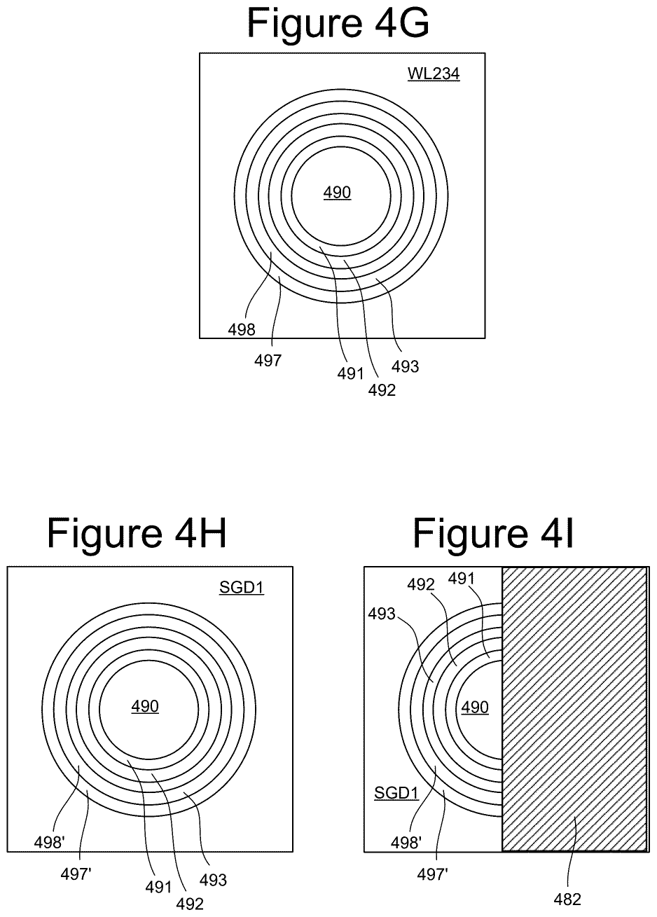

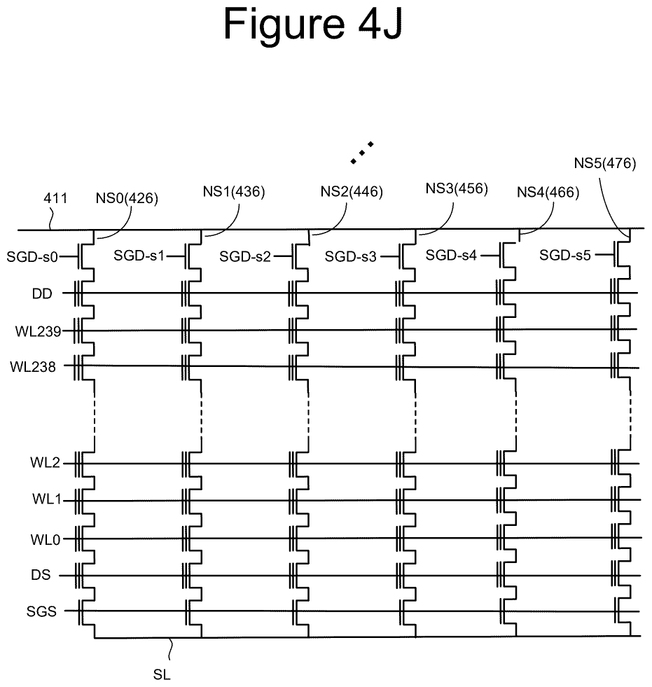

FIG. 4 is a perspective view of a portion of one example embodiment of a monolithic three-dimensional memory array/structure that can comprise memory structure 202, which includes a plurality of on-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example, one of the dielectric layers is marked as D and one of the conductive layers (also called word line layers) is marked as W. The number of alternating dielectric layers and conductive layers can vary based on specific implementation requirements. As will be explained below, in one embodiment the alternating dielectric layers and conductive layers are divided into six (or a different number of) regions by isolation regions IR. FIG. 4 shows one isolation region IR separating two regions. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three-dimensional monolithic memory array that comprises memory structure 202 is provided below.

FIG. 4A is a block diagram explaining one example organization of memory structure 202, which is divided into two planes 402 and 404. Each plane is then divided into M blocks. In one example, each plane has about 2000 blocks. However, different numbers of blocks and planes can also be used. In one embodiment, a block of memory cells is a unit of erase. That is, all memory cells of a block are erased together. In other embodiments, blocks can be divided into sub-blocks and the sub-blocks can be the unit of erase. Memory cells can also be grouped into blocks for other reasons, such as to organize the memory structure to enable the signaling and selection circuits. In some embodiments, a block represents a group of connected memory cells as the memory cells of a block share a common set of word lines. For example, the word lines for a block are all connected to all the vertical NAND strings for that block. Although FIG. 4A shows two planes 402/404, more or less than two planes can be implemented. In some embodiments, memory structure 202 includes four planes, eight planes or more than eight planes.

FIGS. 4B-4J depict an example three dimensional (“3D”) NAND structure that corresponds to the structure of FIG. 4 and can be used to implement memory structure 202 of FIGS. 2A and 2B. FIG. 4B is a block diagram depicting a top view of a portion 406 of Block 2 of plane 402. As can be seen from FIG. 4B, the block depicted in FIG. 4B extends in the direction of 432. In one embodiment, the memory array has many layers; however, FIG. 4B only shows the top layer.

FIG. 4B depicts a plurality of circles that represent the vertical columns, which correspond to the memory holes. Each of the vertical columns include multiple select transistors (also referred to as a select gate or selection gate) and multiple memory cells. In one embodiment, each vertical column implements a NAND string. For example, FIG. 4B labels a subset of the vertical columns/NAND strings 426, 432, 436, 446. 456, 462, 466, 472, 474 and 476.

FIG. 4B also depicts a set of bit lines 415, including bit lines 411, 412, 413, 414, . . . 419. FIG. 4B shows twenty-four-bit lines because only a portion of the block is depicted. It is contemplated that more than twenty-four-bit lines connected to vertical columns of the block. Each of the circles representing vertical columns has an “x” to indicate its connection to one bit line. For example, bit line 411 is connected to vertical columns 426, 436, 446, 456, 466 and 476.

The block depicted in FIG. 4B includes a set of isolation regions 480, 482, 484, 486 and 488, which are formed of SiO₂; however, other dielectric materials can also be used. Isolation regions 480, 482, 484, 486 and 488 serve to divide the top layers of the block into six regions; for example, the top layer depicted in FIG. 4B is divided into regions 420, 430, 440, 450, 460 and 470. In one embodiment, the isolation regions only divide the layers used to implement select gates so that NAND strings in different regions can be independently selected. In one example implementation, a bit line only connects to one vertical column/NAND string in each of regions 420, 430, 440, 450, 460 and 470. In that implementation, each block has twenty-four rows of active columns and each bit line connects to six rows in each block. In one embodiment, all of the six vertical columns/NAND strings connected to a common bit line are connected to the same word line (or set of word lines); therefore, the system uses the drain side selection lines to choose one (or another subset) of the six to be subjected to a memory operation (program, verify, read, and/or erase).

Although FIG. 4B shows each region 420, 430, 440, 450, 460 and 470 having four rows of vertical columns, six regions and twenty-four rows of vertical columns in a block, those exact numbers are an example implementation. Other embodiments may include more or less regions per block, more or less rows of vertical columns per region and more or less rows of vertical columns per block. FIG. 4B also shows the vertical columns being staggered. In other embodiments, different patterns of staggering can be used. In some embodiments, the vertical columns are not staggered.

FIG. 4C depicts a portion of one embodiment of a three-dimensional memory structure 202 showing a cross-sectional view along line AA of FIG. 4B. This cross-sectional view cuts through vertical columns (NAND strings) 472 and 474 of region 470 (see FIG. 4B). The structure of FIG. 4C includes three drain side select layers SGD0, SGD1 and SGD2 (that form select lines); three source side select layers SGS0, SGS1, and SGS2 (that form select lines); three dummy word line layers DD0, DD1, and DDS; two hundred and forty word line layers WL0-WL239 for connecting to data memory cells, and dielectric layers DL0-DL249. Other embodiments can implement more or less than the numbers described above for FIG. 4C. In one embodiment, SGD0, SGD1 and SGD2 are connected together; and SGDS0, SGS1 and SGS2 are connected together.

Vertical columns 472 and 474 are depicted protruding through the drain side select layers, source side select layers, dummy word line layers and word line layers. In one embodiment, each vertical column comprises a vertical NAND string. Below the vertical columns and the layers listed below are substrate 453, an insulating film 454 on the substrate, and source line SL. The NAND string of vertical column 442 has a source end at a bottom of the stack and a drain end at a top of the stack. As in agreement with FIG. 4B, FIG. 4C show vertical column 442 connected to bit line 414 via connector 417.

For ease of reference, drain side select layers; source side select layers, dummy word line layers and data word line layers collectively are referred to as the conductive layers. In one embodiment, the conductive layers are made from a combination of TiN and Tungsten. In other embodiments, other materials can be used to form the conductive layers, such as doped polysilicon, metal such as Tungsten or metal silicide. In some embodiments, different conductive layers can be formed from different materials. Between conductive layers are dielectric layers DL0-DL249. For example, dielectric layers DL240 is above word line layer WL235 and below word line layer WL236. In one embodiment, the dielectric layers are made from SiO₂. In other embodiments, other dielectric materials can be used to form the dielectric layers.

The non-volatile memory cells are formed along vertical columns which extend through alternating conductive and dielectric layers in the stack. In one embodiment, the memory cells are arranged in NAND strings. The word line layers WL0-W239 connect to memory cells (also called data memory cells). Dummy word line layers DD0, DD1 and DS connect to dummy memory cells. A dummy memory cell does not store and is not eligible to store host data (data provided from the host or entity outside of the storage system 100), such as data from a user of the host), while a data memory cell is eligible to store host data. Host data can be contrasted with system data that is generated by memory system 100 (e.g., L2P tables). In some embodiments, data memory cells and dummy memory cells may have a same structure. Drain side select layers SGD0, SGD1, and SGD2 are used to electrically connect and disconnect NAND strings from bit lines. Source side select layers SGS0, SGS1, and SGS2 are used to electrically connect and disconnect NAND strings from the source line SL.

FIG. 4C also shows a Joint area. In one embodiment it is expensive and/or challenging to etch so many word line layers intermixed with dielectric layers. To ease this burden, one embodiment includes laying down a first stack of word line layers alternating with dielectric layers, laying down the Joint area, and laying down a second stack of word line layers alternating with dielectric layers. The Joint area is positioned between the first stack and the second stack. The Joint area is used to connect to the first stack to the second stack. In one embodiment, the Joint area is made from the same materials as the word line layers. In one example set of implementations, the plurality of word lines (control lines) comprises a first stack of alternating word line layers and dielectric layers, a second stack of alternating word line layers and dielectric layers, and a joint area between the first stack and the second stack, as depicted in FIG. 4C.

In one embodiment, a block is divided into sub-blocks. For example, the first/lower stack of each vertical column is part of a lower sub-block SB0 and the second/upper stack is of each vertical column is part of an upper sub-block SB1.

FIG. 4D depicts a portion of one embodiment of a three-dimensional memory structure 202 showing a cross-sectional view along line BB of FIG. 4B. This cross-sectional view cuts through vertical columns (NAND strings) 432 and 434 of region 430 (see FIG. 4B). FIG. 4D shows the same alternating conductive and dielectric layers as FIG. 4C. FIG. 4D also shows isolation region 482. Isolation regions 480, 482, 484, 486 and 488) occupy space that would have been used for a portion of the memory holes/vertical columns/NAND strings. For example, isolation region 482 occupies space that would have been used for a portion of vertical column 434. More specifically, a portion (e.g., half the diameter) of vertical column 434 has been removed in layers SDG0, SGD1, SGD2, and DD0 to accommodate isolation region 482. Thus, while most of the vertical column 434 is cylindrical (with a circular cross section), the portion of vertical column 434 in layers SDG0, SGD1, SGD2, and DD0 has a semi-circular cross section. In one embodiment, after the stack of alternating conductive and dielectric layers is formed, the stack is etched to create space for the isolation region and that space is then filled in with SiO₂.

FIG. 4E depicts a portion of one embodiment of a three-dimensional memory structure 202 showing a cross-sectional view along line CC of FIG. 4B. This cross-sectional view cuts through vertical columns (NAND strings) 452 and 462 (see FIG. 4B). FIG. 4E shows the same alternating conductive and dielectric layers as FIG. 4C. FIG. 4E also shows isolation region 486 cutting into vertical columns (NAND string) 452.

FIG. 4F depicts a cross-sectional view of region 429 of FIG. 4C that includes a portion of vertical column 472. In one embodiment, the vertical columns are round; however, in other embodiments other shapes can be used. In one embodiment, vertical column 472 includes an inner core layer 490 that is made of a dielectric, such as SiO₂. Other materials can also be used. Surrounding inner core 490 is polysilicon channel 491. Materials other than polysilicon can also be used. Note that it is the channel 491 that connects to the bit line and the source line. Surrounding channel 491 is a tunneling dielectric 492. In one embodiment, tunneling dielectric 492 has an ONO structure. Surrounding tunneling dielectric 492 is charge trapping layer 493, such as (for example) Silicon Nitride. Other memory materials and structures can also be used. The technology described herein is not limited to any particular material or structure.

FIG. 4F depicts dielectric layers DL239, DL240, DL241, DL242 and DLL43, as well as word line layers WL234, WL235, WL236, WL237, and WL238. Each of the word line layers includes a word line region 496 surrounded by an aluminum oxide layer 497, which is surrounded by a blocking oxide layer 498. In other embodiments, the blocking oxide layer can be a vertical layer parallel and adjacent to charge trapping layer 493. The physical interaction of the word line layers with the vertical column forms the memory cells. Thus, a memory cell, in one embodiment, comprises channel 491, tunneling dielectric 492, charge trapping layer 493, blocking oxide layer 498, aluminum oxide layer 497 and word line region 496. For example, word line layer WL238 and a portion of vertical column 472 comprise a memory cell MC1. Word line layer WL237 and a portion of vertical column 472 comprise a memory cell MC2. Word line layer WL236 and a portion of vertical column 472 comprise a memory cell MC3. Word line layer WL235 and a portion of vertical column 472 comprise a memory cell MC4. Word line layer WL234 and a portion of vertical column 472 comprise a memory cell MC5. In other architectures, a memory cell may have a different structure; however, the memory cell would still be the storage unit.

When a memory cell is programmed, electrons are stored in a portion of the charge trapping layer 493 which is associated with (e.g. in) the memory cell. These electrons are drawn into the charge trapping layer 493 from the channel 491, through the tunneling dielectric 492, in response to an appropriate voltage on word line region 496. The threshold voltage (Vth) of a memory cell is increased in proportion to the amount of stored charge. In one embodiment, the programming is achieved through Fowler-Nordheim tunneling of the electrons into the charge trapping layer. During an erase operation, the electrons return to the channel or holes are injected into the charge trapping layer to recombine with electrons. In one embodiment, erasing is achieved using hole injection into the charge trapping layer via a physical mechanism such as GIDL.

FIG. 4G shows a cross section of vertical column 472 of FIG. 4F, cut through MC5. Thus, FIG. 4G depicts word line layer WL234, inner core 490, channel 491, tunneling dielectric 492, charge trapping layer 493, aluminum oxide layer 497, and blocking oxide layer 498.

FIG. 4H shows a cross section of vertical column 472 of FIG. 4F, cut through SGD1 (a select gate layer implementing a select gate). Thus, FIG. 4H depicts drain side select line layer SGD1, inner core 490, channel 491, tunneling dielectric 492, charge trapping layer 493, aluminum oxide layer 497, and blocking oxide layer 498.

FIG. 4I shows a cross section of vertical column 434 of FIG. 4D, cut through SGD1. Thus, FIG. 4I depicts drain side select line layer SGD1, inner core 490, channel 491, tunneling dielectric 492, charge trapping layer 493, aluminum oxide layer 497, and blocking oxide layer 498. FIG. 4I also shows a portion of isolation region 482. As can be seen in FIG. 4I, the select gate (select gate layer and select line layer) of vertical column 434 is semicircular in shape (or partially circular in shape) due to vertical column (NAND string) 434 intersecting isolation region 482.

FIG. 4J is a schematic diagram of a portion of the memory array 202 depicted in FIGS. 4-4I. FIG. 4J shows physical data word lines WL0-WL239 running across the entire block. The structure of FIG. 4J corresponds to a portion 306 in Block 2 of Figure A, including bit line 411. Within the block, in one embodiment, each bit line is connected to six NAND strings. Thus, FIG. 4J shows bit line connected to NAND string NS0 (which corresponds to vertical column 426), NAND string NS1 (which corresponds to vertical column 436), NAND string NS2 (which corresponds to vertical column 446), NAND string NS3 (which corresponds to vertical column 456), NAND string NS4 (which corresponds to vertical column 466), and NAND string NS5 (which corresponds to vertical column 476). As mentioned above, in one embodiment, SGD0, SGD1 and SGD2 are connected together to operate as a single logical select gate for each sub-block separated by isolation regions (480, 482, 484, 486 and 486) to form SGD-s0, SGD-s1, SGD-s2, SGD-s3, SGD-s4, and SGD-s5. SGS0, SG1 and SGS2 are also connected together to operate as a single logical select gate that is represented in FIG. 4E as SGS. Although the select gates SGD-s0, SGD-s1, SGD-s2, SGD-s3, SGD-s4, and SGD-s5 are isolated from each other due to the isolation regions, the data word lines WL0-WL239 of each sub-block are connected together.

The isolation regions (480, 482, 484, 486 and 486) are used to allow for separate control of the above-described regions. A first sub-block corresponds to those vertical NAND strings controlled by SGD-s0. A second sub-block corresponds to those vertical NAND strings controlled by SGD-s1. A third sub-block corresponds to those vertical NAND strings controlled by SGD-s2. A fourth sub-block corresponds to those vertical NAND strings controlled by SGD-s3. A fifth sub-block corresponds to those vertical NAND strings controlled by SGD-s4. A sixth sub-block corresponds to those vertical NAND strings controlled by SGD-s5.

FIG. 4J only shows the NAND strings connected to bit line 411. However, a full schematic of the block would show every bit line and six vertical NAND strings connected to each bit line.

Although the example memories of FIGS. 4-4J are three-dimensional memory structure that include vertical NAND strings with charge-trapping material, other (2D and 3D) memory structures can also be used with the technology described herein.

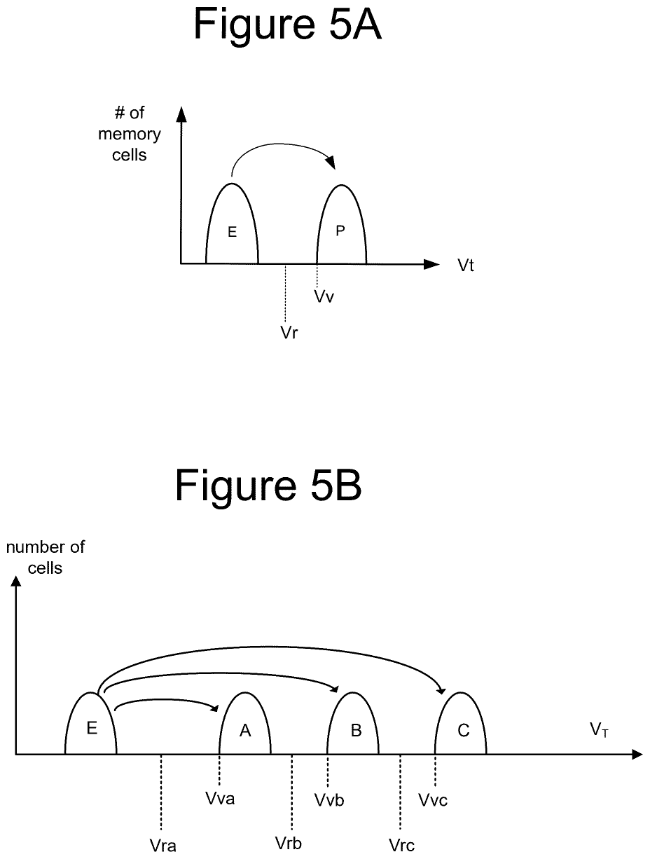

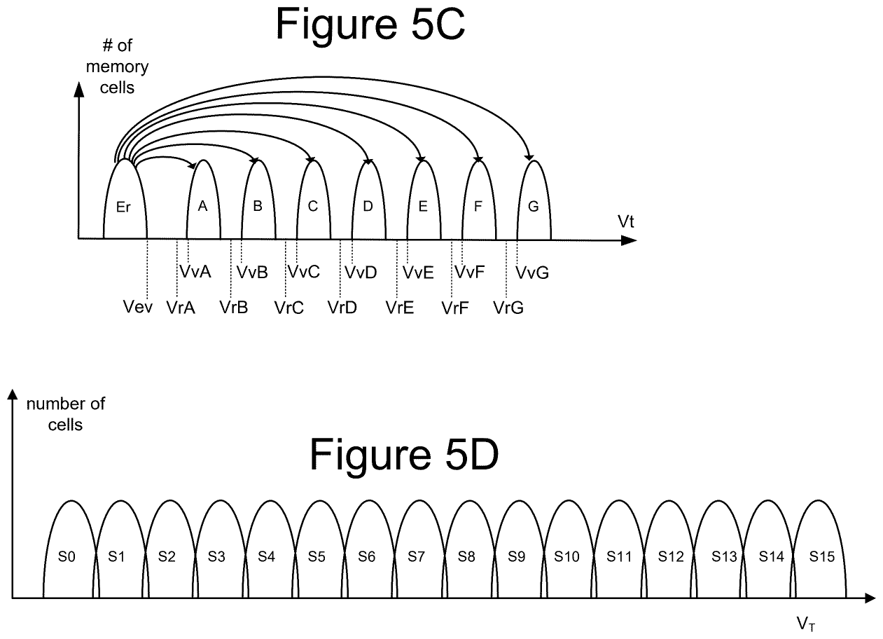

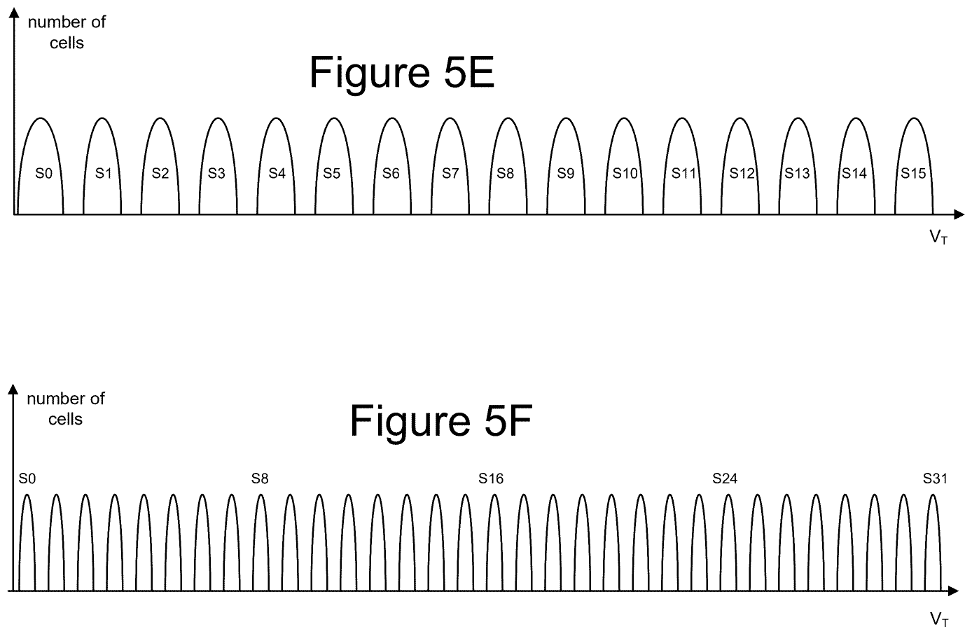

The memory systems discussed above can be erased, programmed and read. At the end of a successful programming process, the threshold voltages of the memory cells should be within one or more distributions of threshold voltages for programmed memory cells or within a distribution of threshold voltages for erased memory cells, as appropriate. FIG. 5A is a graph of threshold voltage versus number of memory cells, and illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data. FIG. 5A shows two threshold voltage distributions: E and P. Threshold voltage distribution E corresponds to an erased data state. Threshold voltage distribution P corresponds to a programmed data state. Memory cells that have threshold voltages in threshold voltage distribution E are, therefore, in the erased data state (e.g., they are erased). Memory cells that have threshold voltages in threshold voltage distribution P are, therefore, in the programmed data state (e.g., they are programmed). In one embodiment, erased memory cells store data “1” and programmed memory cells store data “0.” FIG. 5A depicts read compare voltage Vr. By testing (e.g., performing one or more sense operations) whether the threshold voltage of a given memory cell is above or below Vr, the system can determine a memory cell is erased (state E) or programmed (state P). FIG. 5A also depicts verify reference voltage Vv. In some embodiments, when programming memory cells to data state P, the system will test whether those memory cells have a threshold voltage greater than or equal to Vv.

FIGS. 5B-F illustrate example threshold voltage distributions for the memory array when each memory cell stores multiple bit per memory cell data. Memory cells that store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data. In the example embodiment of FIG. 5B, each memory cell stores two bits of data. Other embodiments may use other data capacities per memory cell (e.g., such as three, four, five or six bits of data per memory cell).

FIG. 5B shows a first threshold voltage distribution E for erased memory cells. Three threshold voltage distributions A, B and C for programmed memory cells are also depicted. In one embodiment, the threshold voltages in the distribution E are negative and the threshold voltages in distributions A, B and C are positive. Each distinct threshold voltage distribution of FIG. 5B corresponds to predetermined values for the set of data bits. In one embodiment, each bit of data of the two bits of data stored in a memory cell are in different logical pages, referred to as a lower page (LP) and an upper page (UP). In other embodiments, all bits of data stored in a memory cell are in a common logical page. The specific relationship between the data programmed into the memory cell and the threshold voltage levels of the cell depends upon the data encoding scheme adopted for the cells. Table 1 provides an example encoding scheme.

TABLE 1

| | E | A | B | C |
|---|---|---|---|---|
| LP | 1 | 0 | 0 | 1 |
| UP | 1 | 1 | 0 | 0 |

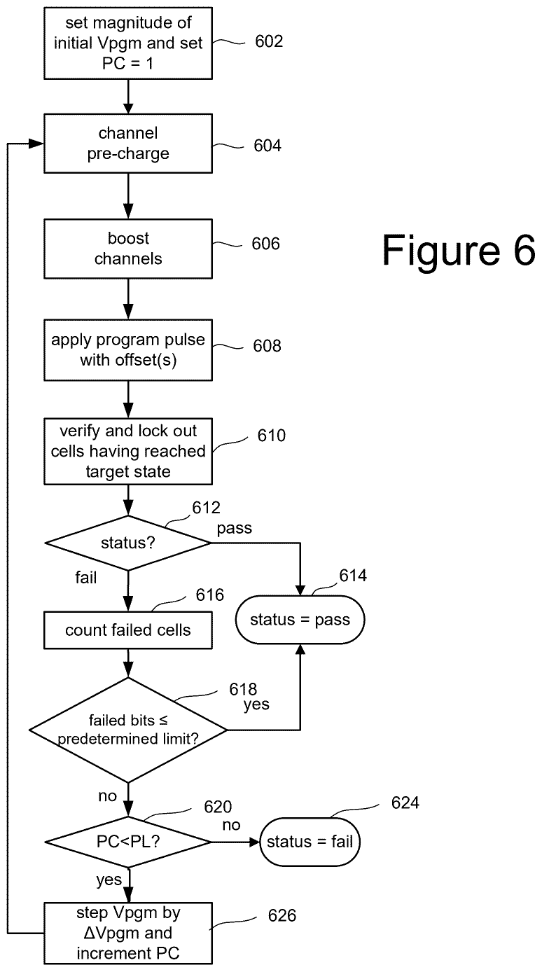

In one embodiment, known as full sequence programming, memory cells can be programmed from the erased data state E directly to any of the programmed data states A, B or C using the process of FIG. 6 (discussed below). For example, a population of memory cells to be programmed may first be erased so that all memory cells in the population are in erased data state E. Then, a programming process is used to program memory cells directly into data states A, B, and/or C. For example, while some memory cells are being programmed from data state E to data state A, other memory cells are being programmed from data state E to data state B and/or from data state E to data state C. The arrows of FIG. 5B represent the full sequence programming. In some embodiments, data states A-C can overlap, with memory controller 120 (or control die 211) relying on error correction to identify the correct data being stored.

FIG. 5C depicts example threshold voltage distributions for memory cells where each memory cell stores three bits of data per memory cells (which is another example of MLC data). FIG. 5C shows eight threshold voltage distributions, corresponding to eight data states. The first threshold voltage distribution (data state) Er represents memory cells that are erased. The other seven threshold voltage distributions (data states) A-G represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected. Table 2 provides an example of an encoding scheme for embodiments in which each bit of data of the three bits of data stored in a memory cell are in different logical pages, referred to as a lower page (LP), middle page (MP) and an upper page (UP).

TABLE 2

| | Er | A | B | C | D | E | F | G |
|---|---|---|---|---|---|---|---|---|
| UP | 1 | 1 | 1 | 0 | 0 | 0 | 0 | 1 |
| MP | 1 | 1 | 0 | 0 | 1 | 1 | 0 | 0 |
| LP | 1 | 0 | 0 | 0 | 0 | 1 | 1 | 1 |

FIG. 5C shows seven read compare voltages, VrA, VrB, VrC, VrD, VrE, VrF, and VrG for reading data from memory cells. By testing (e.g., performing sense operations) whether the threshold voltage of a given memory cell is above or below the seven read compare voltages, the system can determine what data state (i.e., A, B, C, D, . . . ) a memory cell is in.

FIG. 5C also shows seven verify compare voltages, VvA, VvB, VvC, VvD, VVE, VvF, and VvG. In some embodiments, when programming memory cells to data state A, the system will test whether those memory cells have a threshold voltage greater than or equal to VvA. When programming memory cells to data state B, the system will test whether the memory cells have threshold voltages greater than or equal to VvB. When programming memory cells to data state C, the system will determine whether memory cells have their threshold voltage greater than or equal to VvC. When programming memory cells to data state D, the system will test whether those memory cells have a threshold voltage greater than or equal to VvD. When programming memory cells to data state E, the system will test whether those memory cells have a threshold voltage greater than or equal to VvE. When programming memory cells to data state F, the system will test whether those memory cells have a threshold voltage greater than or equal to VvF. When programming memory cells to data state G, the system will test whether those memory cells have a threshold voltage greater than or equal to VvG. FIG. 5C also shows Vev, which is a voltage level to test whether a memory cell has been properly erased.

In an embodiment that utilizes full sequence programming, memory cells can be programmed from the erased data state Er directly to any of the programmed data states A-G using the process of FIG. 6 (discussed below). For example, a population of memory cells to be programmed may first be erased so that all memory cells in the population are in erased data state Er. Then, a programming process is used to program memory cells directly into data states A, B, C, D, E, F, and/or G. For example, while some memory cells are being programmed from data state ER to data state A, other memory cells are being programmed from data state ER to data state B and/or from data state ER to data state C, and so on. The arrows of FIG. 5C represent the full sequence programming. In some embodiments, data states A-G can overlap, with control die 211 and/or memory controller 120 relying on error correction to identify the correct data being stored. Note that in some embodiments, rather than using full sequence programming, the system can use multi-pass programming processes known in the art.

In general, during verify operations and read operations, the selected word line is connected to a voltage (one example of a reference signal), a level of which is specified for each read operation (e.g., see read compare voltages VrA, VrB, VrC, VrD, VrE, VrF, and VrG, of FIG. 5C) or verify operation (e.g. see verify target voltages VvA, VvB, VvC, VvD, VvE, VvF, and VvG of FIG. 5C) in order to determine whether a threshold voltage of the concerned memory cell has reached such level. After applying the word line voltage, the conduction current of the memory cell is measured to determine whether the memory cell turned on (conducted current) in response to the voltage applied to the word line. If the conduction current is measured to be greater than a certain value, then it is assumed that the memory cell turned on and the voltage applied to the word line is greater than the threshold voltage of the memory cell. If the conduction current is not measured to be greater than the certain value, then it is assumed that the memory cell did not turn on and the voltage applied to the word line is not greater than the threshold voltage of the memory cell. During a read or verify process, the unselected memory cells are provided with one or more read pass voltages (also referred to as bypass voltages) at their control gates so that these memory cells will operate as pass gates (e.g., conducting current regardless of whether they are programmed or erased).

There are many ways to measure the conduction current of a memory cell during a read or verify operation. In one example, the conduction current of a memory cell is measured by the rate it discharges or charges a dedicated capacitor in the sense amplifier. In another example, the conduction current of the selected memory cell allows (or fails to allow) the NAND string that includes the memory cell to discharge a corresponding bit line. The voltage on the bit line is measured after a period of time to see whether it has been discharged or not. Note that the technology described herein can be used with different methods known in the art for verifying/reading. Other read and verify techniques known in the art can also be used.

FIG. 5D depicts threshold voltage distributions when each memory cell stores four bits of data, which is another example of MLC data. FIG. 5D depicts that there may be some overlap between the threshold voltage distributions (data states) S0-S15. The overlap may occur due to factors such as memory cells losing charge (and hence dropping in threshold voltage). Program disturb can unintentionally increase the threshold voltage of a memory cell. Likewise, read disturb can unintentionally increase the threshold voltage of a memory cell. Over time, the locations of the threshold voltage distributions may change. Such changes can increase the bit error rate, thereby increasing decoding time or even making decoding impossible. Changing the read compare voltages can help to mitigate such effects. Using ECC during the read process can fix errors and ambiguities. Note that in some embodiments, the threshold voltage distributions for a population of memory cells storing four bits of data per memory cell do not overlap and are separated from each other; for example, as depicted in FIG. 5E. The threshold voltage distributions of FIG. 5D will include read compare voltages and verify compare voltages, as discussed above.

When using four bits per memory cell, the memory can be programmed using the full sequence programming discussed above, or multi-pass programming processes known in the art. Each threshold voltage distribution (data state) of FIG. 5D corresponds to predetermined values for the set of data bits. The specific relationship between the data programmed into the memory cell and the threshold voltage levels of the cell depends upon the data encoding scheme adopted for the cells. Table 3 provides an example of an encoding scheme for embodiments in which each bit of data of the four bits of data stored in a memory cell are in different logical pages, referred to as a lower page (LP), middle page (MP), an upper page (UP) and top page (TP).

TABLE 3

| | S0 | S1 | S2 | S3 | S4 | S5 | S6 | S7 | S8 | S9 | S10 | S11 | S12 | S13 | S14 | S15 |
|---|---|---|---|---|---|---|---|---|---|---|---|---|---|---|---|---|
| TP | 1 | 1 | 1 | 1 | 1 | 0 | 0 | 0 | 0 | 0 | 1 | 1 | 0 | 0 | 0 | 1 |
| UP | 1 | 1 | 0 | 0 | 0 | 0 | 0 | 0 | 1 | 1 | 1 | 1 | 1 | 1 | 0 | 0 |
| MP | 1 | 1 | 1 | 0 | 0 | 0 | 0 | 1 | 1 | 0 | 0 | 0 | 0 | 1 | 1 | 1 |
| LP | 1 | 0 | 0 | 0 | 1 | 1 | 0 | 0 | 0 | 0 | 0 | 1 | 1 | 1 | 1 | 1 |

FIG. 5F depicts threshold voltage distributions when each memory cell stores five bits of data, which is another example of MLC data. In one example implementation, when memory cells store five bits of data, the data is stored in any of thirty-two data state (e.g., S0-S31).

FIG. 6 is a flowchart describing one embodiment of a process for programming memory cells. For purposes of this document, the term program and programming are synonymous with write and writing. In one example embodiment, the process of FIG. 6 is performed for memory array 202 using the one or more control circuits (e.g., system control logic 260, column control circuitry 210, row control circuitry 220) discussed above. In one example embodiment, the process of FIG. 6 is performed by integrated memory assembly 207 using the one or more control circuits (e.g., system control logic 260, column control circuitry 210, row control circuitry 220) of control die 211 to program memory cells on memory die 201. The process includes multiple loops, each of which includes a program phase and a verify phase. The process of FIG. 6 is performed to implement the full sequence programming, as well as other programming schemes including multi-pass programming, which comprises programming processes that use multiple passes to complete programming. When implementing multi-pass programming, the process of FIG. 6 is used to implement any/each pass of the multi-pass programming process.

Typically, the program voltage applied to the control gates (via a selected data word line) during a program operation is applied as a series of program pulses (e.g., voltage pulses). Between programming pulses are a set of verify pulses (e.g., voltage pulses) to perform verification. In many implementations, the magnitude of the program pulses is increased with each successive pulse by a predetermined step size. In step 602 of FIG. 6, the programming voltage signal (Vpgm) is initialized to the starting magnitude (e.g., ~12-16V or another suitable level) and a program counter PC maintained by state machine 262 is initialized at 1. In one embodiment, the group of memory cells selected to be programmed (referred to herein as the selected memory cells) are programmed concurrently and are all connected to the same word line (the selected word line). There will likely be other memory cells that are not selected for programming (unselected memory cells) that are also connected to the selected word line. That is, the selected word line will also be connected to memory cells that are supposed to be inhibited from programming. Additionally, as memory cells reach their intended target data state, they will be inhibited from further programming. Those NAND strings (e.g., unselected NAND strings) that include memory cells connected to the selected word line that are to be inhibited from programming have their channels boosted to inhibit programming. When a channel has a boosted voltage, the voltage differential between the channel and the word line is not large enough to cause programming. To assist in the boosting, in step 604 the control die will pre-charge channels of NAND strings that include memory cells connected to the selected word line that are to be inhibited from programming. In step 606, NAND strings that include memory cells connected to the selected word line that are to be inhibited from programming have their channels boosted to inhibit programming. Such NAND strings are referred to herein as “unselected NAND strings.” In one embodiment, the unselected word lines receive one or more boosting voltages (e.g., ~7-11 volts), also referred to as pass voltages, to perform boosting schemes. A program inhibit voltage is applied to the bit lines coupled with the unselected NAND string. In one embodiment, for example, the channel is pre-charged to ~2 volts in step 604 and then floated. In step 606, the channel is boosted up from 2 volts to a boosting voltage of approximately 8-10 volts.

In step 608, a program voltage pulse of the programming voltage signal Vpgm is applied to the selected word line (the word line selected for programming). In some embodiments, the magnitude and/or pulse width of the program voltage pulse can be modified from the standard magnitude and/or pulse width by one or more offsets, as described below. If a memory cell on a NAND string should be programmed, then the corresponding bit line is biased at a program enable voltage. In step 608, the program pulse is concurrently applied to all memory cells connected to the selected word line so that all of the memory cells connected to the selected word line are programmed concurrently (unless they are inhibited from programming). That is, they are programmed at the same time or during overlapping times (both of which are considered concurrent). In this manner all of the memory cells connected to the selected word line will concurrently have their threshold voltage change, unless they are inhibited from programming.

In step 610, program verify is performed and memory cells that have reached their target states are locked out from further programming by the control die. Step 610 includes performing verification of programming by sensing at one or more verify compare levels. In one embodiment, the verification process is performed by testing whether the threshold voltages of the memory cells selected for programming have reached the appropriate verify compare voltage. In one embodiment that corresponds to FIG. 5C, the process of FIG. 6 is concurrently performed for memory cells being programmed to data states A, B, C, D, E, F and G. In one embodiment, step 610 can include testing for each of data states A, B, C, D, E, F and G (e.g., testing to see whether memory cells have threshold voltages greater than VvA, VvB, VvC, VvD, VvE, VvF, and VvG). In another embodiment, the system only tests for a subset of data states A, B, C, D, E, F and G during each loop of steps 604-626 based on the current threshold voltages of the memory cells, in what is known as a smart verify process. In step 610, a memory cell may be locked out after the memory cell has been verified (by a test of the Vt) that the memory cell has reached its target state.

If, in step 612, it is determined that all of the memory cells have reached their target threshold voltages (pass), the programming process is complete and successful because all selected memory cells were programmed and verified to their target states. A status of “PASS” is reported in step 614. Otherwise, if in step 612, it is determined that not all of the memory cells have reached their target threshold voltages (fail), then the programming process continues to step 616.

In step 616, the number of memory cells that have not yet reached their respective target threshold voltage distribution are counted. That is, the number of memory cells that have, so far, failed to reach their target state are counted. This counting can be done by state machine 262, memory controller 120, or another circuit. In one embodiment, there is one total count, which reflects the total number of memory cells currently being programmed that have failed the last verify step. In another embodiment, separate counts are kept for each data state.

In step 618, it is determined whether the count from step 616 is less than or equal to a predetermined limit. In one embodiment, the predetermined limit is the number of bits that can be corrected by error correction codes (ECC) during a read process for the page of memory cells. If the number of failed cells is less than or equal to the predetermined limit, than the programming process can stop and a status of “PASS” is reported in step 614. In this situation, enough memory cells programmed correctly such that the few remaining memory cells that have not been completely programmed can be corrected using ECC during the read process. In some embodiments, the predetermined limit used in step 618 is below the number of bits that can be corrected by error correction codes (ECC) during a read process to allow for future/additional errors. When programming less than all of the memory cells for a page, or comparing a count for only one data state (or less than all states), than the predetermined limit can be a portion (pro-rata or not pro-rata) of the number of bits that can be corrected by ECC during a read process for the page of memory cells. In some embodiments, the limit is not predetermined. Instead, it changes based on the number of errors already counted for the page, the number of program-erase cycles performed or other criteria.

If the number of failed memory cells is not less than the predetermined limit, then the programming process continues at step 620 and the program counter PC is checked against the program limit value (PL). Examples of program limit values include 6, 12, 16, 19, 20 and 30; however, other values can be used. If the program counter PC is not less than the program limit value PL, then the program process is considered to have failed and a status of FAIL is reported in step 624. If the program counter PC is less than the program limit value PL, then the process continues at step 626 during which time the Program Counter PC is incremented by 1 and the programming voltage signal Vpgm is stepped up to the next magnitude. For example, the next pulse will have a magnitude greater than the previous pulse by a step size ΔVpgm (e.g., a step size of 0.1-1.0 volts). After step 626, the process loops back to step 604 and another program pulse is applied to the selected word line (by the control die) so that another loop (steps 604-626) of the programming process of FIG. 6 is performed.

In some embodiments, memory cells are programmed in an order from the source side to the drain side. For example, first the process of FIG. 6 is performed to program memory cells connected to WL0, followed by using the process of FIG. 6 to program memory cells connected to WL1, followed by using the process of FIG. 6 to program memory cells connected to WL2, followed by using the process of FIG. 6 to program memory cells connected to WL3, . . . followed by using the process of FIG. 6 to program memory cells connected to WL239.

In another embodiment, memory cells are programmed in an order from the drain side to the source side. For example, first the process of FIG. 6 is performed to program memory cells connected to WL239, followed by using the process of FIG. 6 to program memory cells connected to WL238, followed by using the process of FIG. 6 to program memory cells connected to WL237, followed by using the process of FIG. 6 to program memory cells connected to WL236, . . . followed by using the process of FIG. 6 to program memory cells connected to WL1, followed by using the process of FIG. 6 to program memory cells connected to WL0.

In one embodiment memory cells are erased prior to programming, and erasing is the process of changing the threshold voltage of one or more memory cells from a programmed data state to an erased data state. For example, changing the threshold voltage of one or more memory cells from state P to state E of FIG. 5A, from states A/B/C to state E of FIG. 5B, from states A-G to state Er of FIG. 5C or from states S1-S15 to state S0 of FIG. 5D.

One technique to erase memory cells in some memory devices is to bias a p-well (or other types of) substrate to a high voltage to charge up a NAND channel. An erase enable voltage (e.g., a low voltage) is applied to control gates of memory cells while the NAND channel is at a high voltage to erase the non-volatile storage elements (memory cells). Herein, this is referred to as a p-well erase.

Another approach to erasing memory cells is to generate gate induced drain leakage (GIDL) current to charge up the NAND string channel. An erase enable voltage is applied to control gates of the memory cells, while maintaining the NAND string channel potential to erase the memory cells. Herein, this is referred to as GIDL erase. Both p-well erase and GIDL erase may be used to lower the threshold voltage (Vt) of memory cells.

In one embodiment, the GIDL current is generated by causing a drain-to-gate voltage at a select transistor (e.g., SGD and/or SGS). A transistor drain-to-gate voltage that generates a GIDL current is referred to herein as a GIDL voltage. The GIDL current may result when the select transistor drain voltage is significantly higher than the select transistor control gate voltage. GIDL current is a result of carrier generation, i.e., electron-hole pair generation due to band-to-band tunneling and/or trap-assisted generation. In one embodiment, GIDL current may result in one type of carriers, e.g., holes, predominantly moving into NAND channel, thereby raising potential of the channel. The other type of carriers, e.g., electrons, are extracted from the channel, in the direction of a bit line or in the direction of a source line, by an electric field. During erase, the holes may tunnel from the channel to a charge storage region of memory cells and recombine with electrons there, to lower the threshold voltage of the memory cells.

The GIDL current may be generated at either end of the NAND string. A first GIDL voltage may be created between two terminals of a select transistor (e.g., drain side select transistor) that is connected to or near a bit line to generate a first GIDL current. A second GIDL voltage may be created between two terminals of a select transistor (e.g., source side select transistor) that is connected to or near a source line to generate a second GIDL current. Erasing based on GIDL current at only one end of the NAND string is referred to as a one-sided GIDL erase. Erasing based on GIDL current at both ends of the NAND string is referred to as a two-sided GIDL erase.

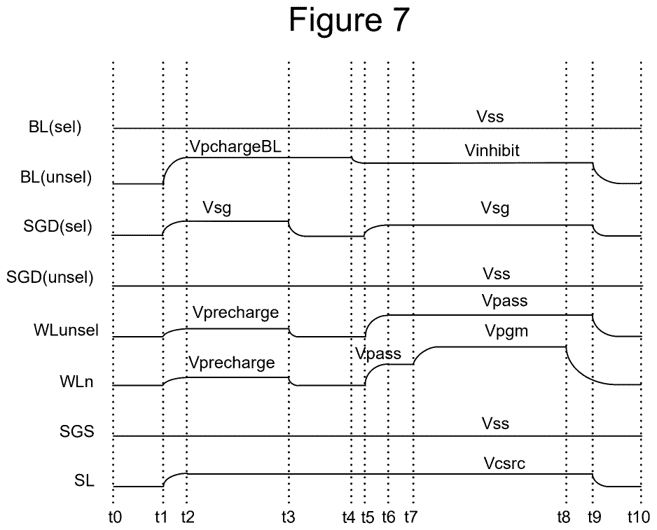

FIG. 7 is a signal diagram describing the behavior of various signals used to control the memory cells during programming. FIG. 7 describes one example implementation of steps 604-608 of FIG. 6 for the following signals: BL (sel), BL (unsel), SGD (sel), SGD (unsel), WLunsel, WLn, SGS, and SL. The signal BL (sel) is the bit line signal applied to bit lines of NAND strings selected to be being programmed. The signal BL (unsel) is the bit line signal applied to unselected bit lines. The signal SGD (sel) is the SGD selection line for the appropriate portion of the block that is selected for programming (see FIG. 4F). The signal SGD (unsel) is the SGD lines that are unselected for the portions of the block that are unselected (see FIG. 4J). The signal WLunsel are the unselected word lines, meaning the word lines that are not connected to memory cells selected for being programmed at this time. The signal WLn is the programming voltage signal being applied to selected word lines in the blocks being simultaneously programmed. The signal SGS represents all the source side selection line (see FIG. 4J). The signal SL is the source line signal.

The signal BL (sel) is kept at Vss or ground during the time period of FIG. 6. At time t1, BL (unsel) is raised from ground to a pre-charge voltage VpchargeBL in order to allow for pre-charging as per step 604 of FIG. 6. At time t4, the unselected bit line voltage BL (unsel) is lowered to Vinhibit and then the voltage is lowered down to ground at time t9. At time t1, SGD (sel) is raised to Vsg which is a voltage high enough to turn on the transistor for the select gate (e.g., 3.5 v). This allows unselected NAND strings to be pre-charged (step 604 of FIG. 6) and selected NAND strings to not be pre-charged. The voltage for SGD (sel) is lowered to ground at time t3, raised to Vsg at t5, and lowered to ground at t9. The SGD (unsel) signal is kept at ground or Vss the entire time period of FIG. 6. The unselected word lines WLunsel is raised to Vprecharge at time t1, lowered to ground at time t3, raised to Vpass (e.g., 7-10v) at time t5, and lowered to ground at time t9. The signal WLunsel is set to Vprecharge in order to allow the pre-charging of step 604 of FIG. 6 and then raised to Vpass in order to allow the boosting of step 606 of FIG. 6. The signal WLn is raised to Vprecharge at time t1, lowered to ground to time t3, raised to Vpass at time t5, raised to Vpgm (the programming voltage) at time t7, and lowered down to ground at time t8. Note that the voltage on WLn between t7 and t8 represents the voltage pulse used for programming (step 608 of FIG. 6). SGS is kept at Vss or ground during the time period of FIG. 6. The source line is raised from ground to Vcsrc (e.g., 2.5-3.5 volts) at time t1 and then lowered to ground at time t9. The time period of t2-t3 corresponds to the pre-charging of the channels of unselected NAND strings as per step 604 of FIG. 6.

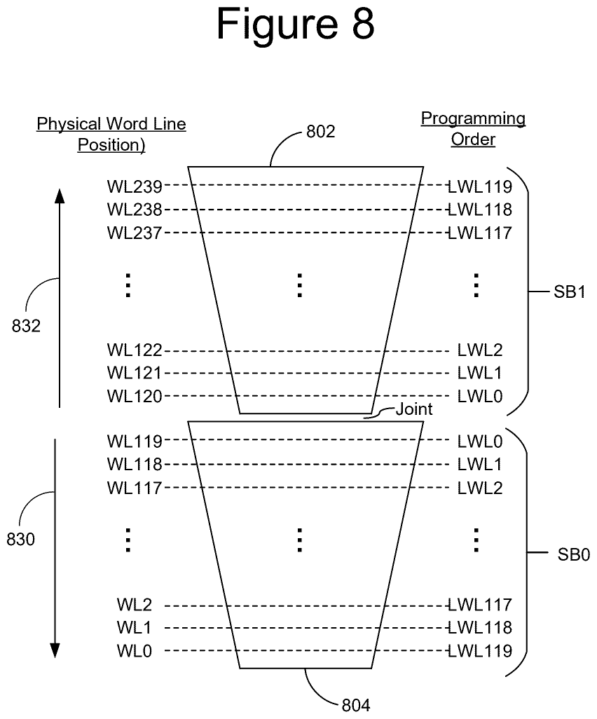

As described above, one embodiment of a memory structure includes NAND strings that are formed by filling the memory holes with materials including a charge-trapping material to create vertical columns of materials that form the memory cells (also referred to as a memory column). For example, FIG. 4F depicts a cross section of vertical column 472. FIGS. 4C-4F shows the vertical column in the shape of a cylinder with perfectly vertical sides. However, in some implementations, the vertical columns have sides that are angled. That is, the vertical columns increase in diameter along the vertical axis from bottom to top. For the embodiments that have lower sets of word lines below the Joint area and upper sets of word lines above the Joint area (see FIGS. 4C), then the plurality of vertical columns increases in diameter along the vertical axis from bottom to top within a sub-block. This situation is graphically depicted in FIG. 8, which shows vertical column 472 divided into a lower memory column 804 and an upper memory column 802, both of which have sides that are angled such that the column increases in diameter along the vertical axis from bottom to top within a sub-block. The diameter of the lower memory column 804 is larger at the top as compared to the bottom within sub-block SB0. The diameter of the upper memory column 802 is larger at the top as compared to the bottom within sub-block SB1.

One step in the process flow to manufacture the memory is the memory hole etch, which defines the lateral shape of the memory cell. Ideally, the etch would be perfectly vertical. However, in reality for some embodiments, the etch is angled. This means that lower layers tend to have memory cells with smaller diameters. It has been observed that memory cells with smaller diameters program faster than memory cells with larger diameters. Therefore, as programming progresses from the lowest physical word line WL0 to the highest physical word line WL119 of the lower vertical column, the programming speed slows down. This pattern of faster to slower repeats when programming memory cells connected to word lines WL120-WL239. To speed up the slower memory cells on higher word lines, a programing voltage with a higher voltage magnitude (e.g., higher initial Vpgm) can be used.

Referring back to FIG. 4, the scaling of 3D NAND flash memory is achieved by increasing the number of word line layers in the stack 401. Increasing the number of layers in the word line stack introduces process complexity, especially on the memory hole formation process because it becomes difficult to realize uniform memory hole dimensions at such high aspect ratios. Additionally, connection of the biasing circuitry and other processing will have increased technical and cost related challenges at higher word line stack levels. The processing to form such structures often needs to tackle issues from high word line stacking and during the development of such devices there are often changing requests the number of word line layers as countermeasure to the processing cost and technical challenges. The request of changing the number of word line layers can happen at any time during the design phase. For example, if during the development of the 3D array structure it is decided by a process team to reduce the number of word lines to, for example, reduce Vth variations, this can lead to costly development delays as the corresponding peripheral circuitry needs to be changed accordingly. Consequently, each time the number of word line layers is changed, the row/logic design and device teams have long schedule delays. Row design changes result in a need to re-design the mapping of the circuitry that controls the biasing of control gates and word lines, leading to long schedule delays.

To address these issues, the following embodiments present a core control gate driver mapping that can stay unchanged, even if the number of word lines are changed. A number of m reserve word lines, which can be added in based on design changes, are added at the top and bottom word line stack, where the reserve word lines have independent control gate drivers, so that removing or keeping reserve word lines would not affect the core control gate driver structure. These 2 m reserve word lines can remain in the product or be partially/fully removed depending on process team process requirements and optimizations, and allow the designers' team to change the total number of required word lines without significant design schedule impact.

In other embodiments, a number of m reserve word lines can be included at the top, bottom, and middle, such as at joint regions of FIG. 8, of the word line stack. The location of the reserve word lines can be selected at critical locations where the design is more likely to have layer options, such as at the joint region between SB0 and SB1 of FIG. 8. Having such reserve word lines at multiple locations can avoid the need for schematic or design changes for the control circuitry when the word line number changes. These reserve word lines can have independent control gate drivers, so that as word lines are removed or added, the core control gate mapping structure need not change, and the 3 m reserve word lines can remain in the product or be partially/fully removed depending on processing requirements and optimizations.

These features can be very useful as products are typically developed on a very limited schedule that can be seriously affected when a process team decides to charge the number of word lines during the design phase. They can be particularly useful with respect to memory cells from edge word lines or critical memory hole regions that can have different characteristics compared to center word lines. By having reserve word lines with separate independent drivers, special voltage biases only for these word lines can be achieved and overall uniform cell characteristics can be realized.

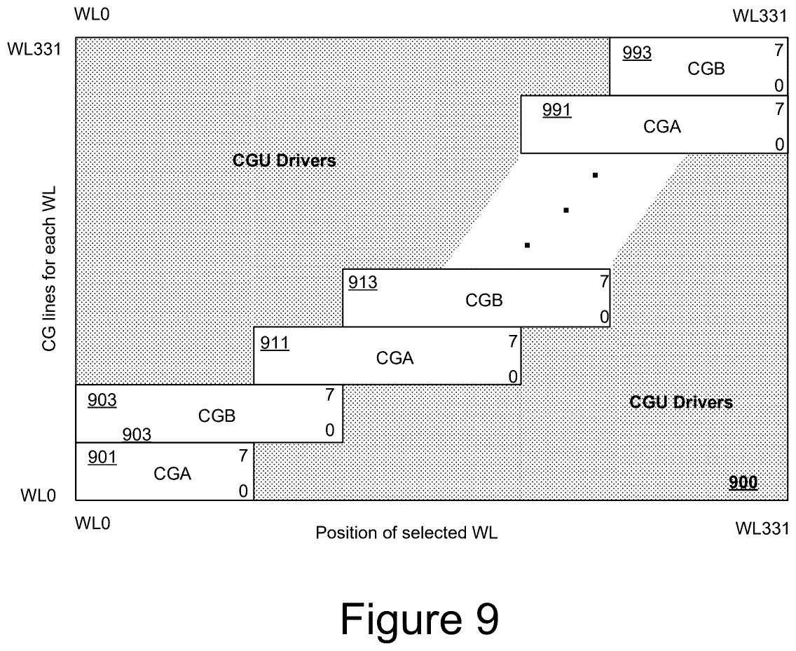

To provide more context, FIG. 9 illustrates an arrangement of control gate drivers for word lines in an example without the inclusion of the reserve word lines. This example is based on a NAND structure with 332 data word lines and schematically represents the layout of the control gate drives for unselected word lines during a memory operation. In one set of embodiments, these control circuits are formed on a control 211 that is then bonded to a memory 201, as in the embodiment of FIG. 2B where they, along with the selected word line drivers, would be part of the array drivers 224. In other embodiments, the control circuitry could be formed on the same die as the memory array, but under the array structure. In a typical NAND memory operation, one word line of block is selected and the other word lines are unselected and have their control gates biased to facilitate the operation on the selected word line. The representation of FIG. 9 is laid out so that the positions of the selected word line (WL) of word lines WL0 to WL331 run up and down and numbered from right to left, while the control gate (CG) lines for biasing the control gates of the unselected word lines run left to right and are number from bottom to top. Relative to the representation of the 3D NAND structure, such as FIG. 4 or 4C, word line WL0 is at the bottom of the stack and WL 331 at the top.

The embodiments here consider the case where the unselected word lines include the general unselected word lines and also allows for the word lines neighboring a selected word line, so as one or a few unselected word lines to one or both sides of the selected word line to be biased differently, such as for local boosting purposes. In FIG. 9, the non-neighbor unselected control gate word line drives are in the regions of the drivers labelled CGU drivers 900. The neighboring unselected control gate drives, or CGN drivers, are in this embodiment split into CGA drivers, for unselected control gate drives for neighbors to one side of the selected word line, and CGB drivers, for unselected control gate drives for neighbors to the other side of the selected word line. This allows for unselected neighboring word lines on the drain side and the source side of the selected word line to be biased to individually to facilitate operation by asymmetric bias conditions for different boost options during programming. To the number of control gate drives in the periphery regions, the CGA and CGB drivers are located close to the selected word lines, resulting up their lying along the rising diagonal for where the indices on both sides match. In this embodiment, the CGA and CGB drivers are grouped in set of 8s, alternating between the CGA drivers and CGB drivers, as shown for CGA block 901 followed by CGB block 903, then CGA block 911 followed by CGB block 913, and alternating in this way in sets of eight word lines across the array up to CGA block 991 followed by CGB block 993. Under the arrangement of FIG. 9, if a processing team changes the number of word lines in the design phase, this will result in a corresponding need to redesign the control circuitry arrangement for the drivers, that can often result in long schedule delays.

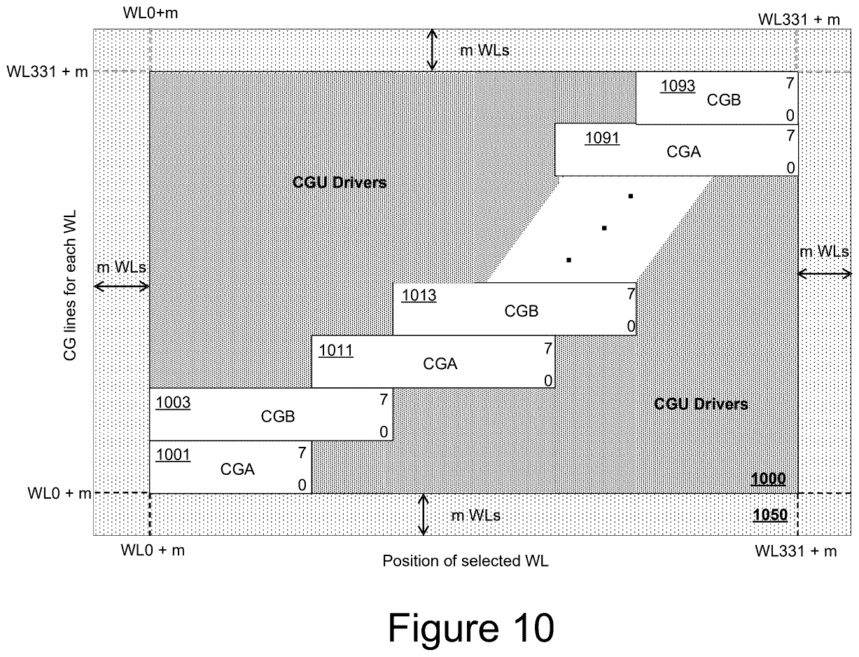

To address this issue, in a first set of aspects, a number of reserve word lines are added at the top, the bottom, or both of the stack of word lines. This allows for adaptation to design alterations the change the number of word lines. An embodiment is shown in FIG. 10.

FIG. 10 illustrates an embodiment for the layout of control gate drivers incorporating reserve word lines. In this example, m reserve word lines are added at both the top and bottom of the word line stack. Although this example adds reserve lines, and the same number of reserve word lines, to both the top and bottom of the word line stack, other embodiments can add reserve word lines to only one side or add differing numbers to the sides. In the representation of FIG. 10, these two sets of m reserve word lines are at the left and at the right of the regular word lines.

More specifically, the central portion of FIG. 10 can be structured as in FIG. 9, with the alternating sets of unselected neighbor word line drivers CGA 1001 and CGB 1003, CGA 1011 and CGB 1013, and extending upward diagonally to CGA 1091 and CGB 1093, and with the other unselected word line control gate drivers 1000 filling out the rest of the central region. To either side are now m word lines, running from WL0 to WL0+m, which begins the 332 (in this example) non-reserve word lines up to WL331+m, followed by a further m reserve word lines, where it is again noted that the reserve word lines respectively represented at left and right in FIG. 10 would be at the bottom and top of the 3D stack. For the 2 m reserve word lines, a corresponding m control gate lines run left to right above and below, where these reserve word lines and control gate lines are in the lightly stippled periphery region 1050.

The two sets of m reserve lines have independent word lines drivers in the region 1050, different than the CGU drivers 1000 and the central CGA and CGB unselected neighbor drivers. If, during the design and development phase, the process team decides to change the number of word lines, there is flexibility because the selected number of the reserve word lines can be altered without affecting the core control gate driver layout design. There will be no need to re-design the CGU, CGA, and CGB drivers again if the word lines again change. Consequently, the number of word lines per block can be altered without significant schedule impact on row design. By placing the reserve word lines at the edges of the stack, they can use the drivers in the region 1050 to apply special biases to fine tune the cell characteristics on these word lines.

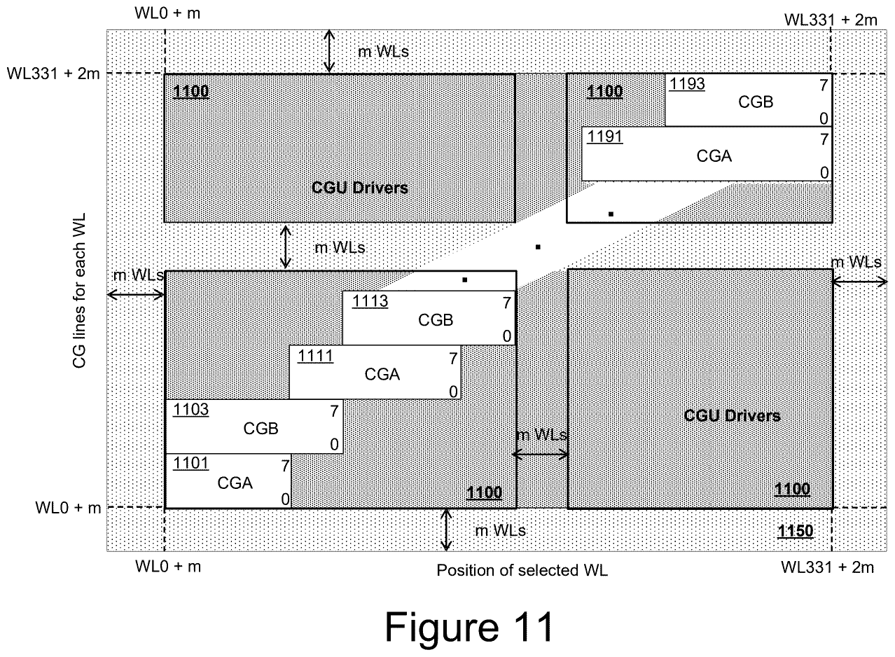

FIG. 11 illustrates a further embodiment that further includes reserve word lines in the central region of a memory block. As described above with respect to FIG. 8, in some embodiments for forming a 3D NAND structure, a first set of alternating word line/dielectric layers are formed, such as for SB0, with a lower memory column 804, with a further set of alternating word line/dielectric layers, such as for SB1, with an upper memory column 802 formed above the joint region. Other embodiments may have multiple such joint regions, particularly as stack heights continue to increase. As with the bottom and top of the word line stack, the word lines in these joint regions often are subject to disturbs and edge effect that can result in changes in word line numbers during the design and development process.

FIG. 11 is laid out and numbered similarly to FIG. 10, with the CGU drivers 1100 in the central regions 1100 and the neighboring unselected word line control gate drivers 1101/1103, 1111/1113, . . . , 1191/1193 running upward diagonally. In addition to the reserve word lines at the top and the bottom of the stack, m reserve word lines are now added to the middle of the word line stack, such as at the joint region or other part of the word line stack that commonly needs a change in word line number during the design process. The added central m word lines have m independent control gate drivers not driven by the CGU and CGA/CGB located in the region of 1150 running left to right between the upper (as represented in FIG. 11) and lower CGU drivers 1100. Relative to FIG. 10, the additional word lines in the middle of the word line stack can be located to target memory hole regions, such as a joint region, that can have critical dimension issues that are most likely to need word line layer options. This arrangement can then accommodate word line changes in these regions without design changes to the word line control gate driver layout.

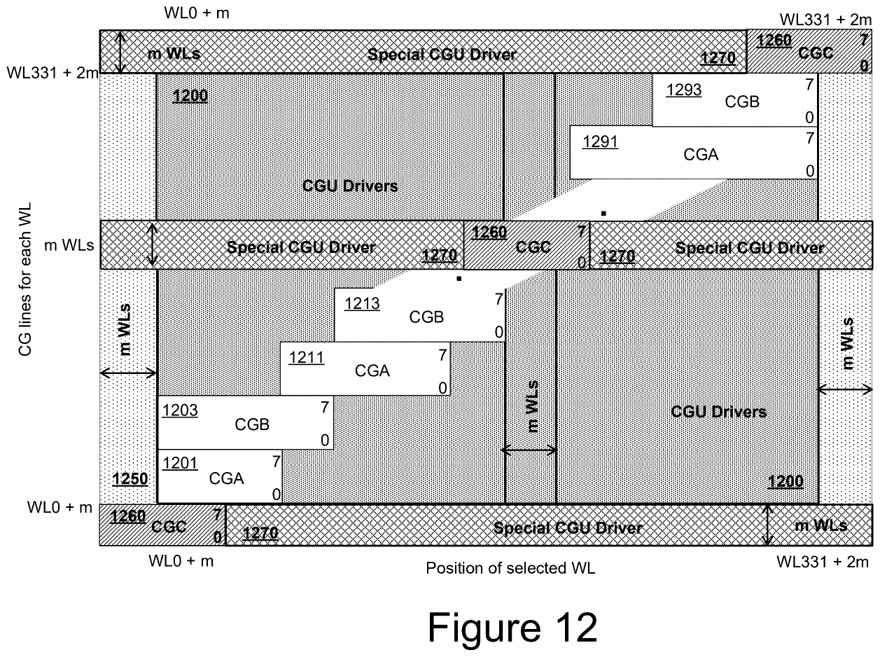

FIG. 12 illustrates another embodiment that includes reserve word lines in the central region of a memory block. As in FIG. 11, m reserve word lines are added on each of the top, middle and bottom of the word line stack, where in this example m=8 word lines are added to each of these regions, but other embodiments can use differing number as can be decided based on processing concerns. The unselected word line control gate drivers CGU 1200 and CGA/CGB 1201/1203, 1211/1213, . . . , 1291/1293, along with those in the regions 1250, can be as describe above with respect to elements CGU 1100, CGA/CGB 1101/1103, 1111/1113, . . . , 1191/1193, and those of the regions 1150.

Unlike the embodiment of FIG. 11, in the embodiment of FIG. 12 the reserve word lines have one common neighboring word line control gate drivers for each of the top, middle, and bottom locations, namely the three sets of CGC drivers 1260 along the diagonal, with the non-reserve neighboring word line drivers CGA/CGB in between. In addition to the neighboring unselected word line control gate CGC drivers 1260, the non-neighbor reserve word lines of each set of reserve word lines have a common special unselected control line drivers 1270. The neighboring unselected word line drivers CGC 1260 and special non-neighbor CGU drivers 1270 can help lower the layout impact since they can be shared by all of the reserve word lines. The reserve word line locations are the same in the embodiments of FIG. 11 and FIG. 12, with the reserve word line drivers arranged differently, such that in the embodiment of FIG. 11 these are not shared, whereas they are shared in the embodiment of FIG. 12.

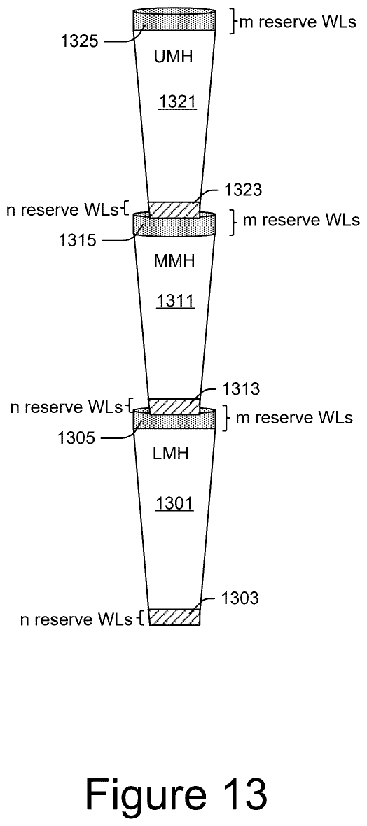

The embodiment of FIG. 10 included reserve word lines at the top and bottom of the word line stack, as these are areas that often undergo design changes in terms of the word line layers during the design and development process. The embodiments of FIGS. 11 and 12 further introduce additional reserve word lines at the joint region between the two memory hole processing regions, which also often undergo design changes in terms of the word line layers during the design and development process. More generally, the 3D NAND memory structure may be fabricated with multiple such intermediate regions where the development and design process could benefit from the incorporation of reserve word lines. This is illustrated with respect to FIG. 13.

FIG. 13 illustrates an embodiment for applying the use of reserve memory lines to a 3-tier example of a multi-tier memory hole process. This example includes an upper memory hole UMH region 1321, a middle memory hole region MMH 1311, and a lower memory hole region LMH 1301. For each of these regions UMH region 1321, MMH 1311, and LMH 1301, this embodiment includes m reserve word lines 1325/1315/1305 at the top of each tier and n reserve word lines 1323/1313/1303 at the bottom of each tier, as these transition regions at the top and bottom of each tier are typically where critical dimension value are critical. As with the embodiment of FIG. 12, each of the m reserve word lines 1325/1315/1305 and n reserve word lines 1323/1313/1303 can have a set of common CGC unselected neighbor word line drivers and common special CGU word line drivers, where the inclusion of these common special drivers can help lower the layout impact since they can be shared by the reserve word lines from different tiers. The same approach can be extended to more than three memory hole layers.

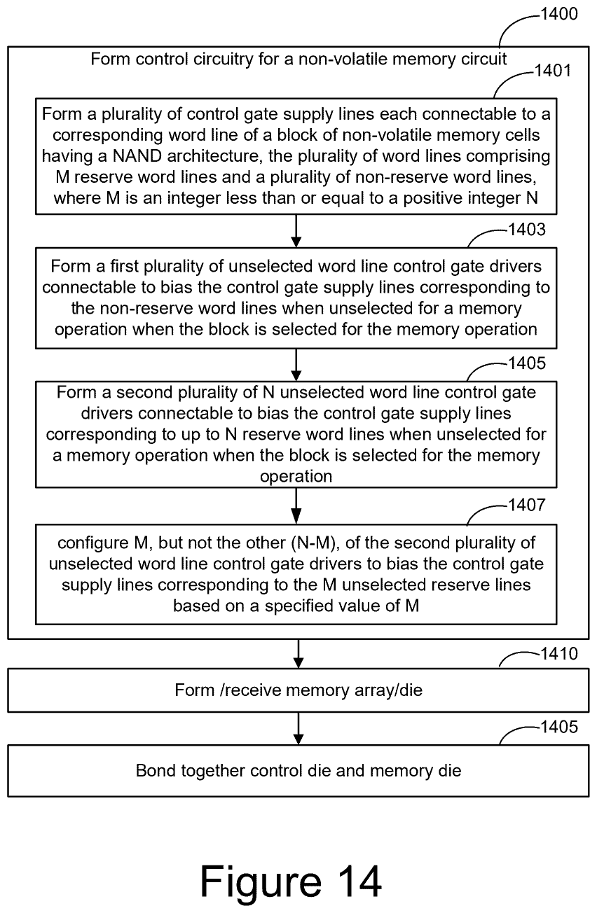

FIG. 14 is a flowchart of an embodiment for forming a memory device with the control circuitry presented with respect to FIGS. 10-13. Step 1400 is the forming of the control circuitry, such as in one of the embodiments of FIGS. 10-13. In step 1401, the control gate supply lines for the word lines that run left to right in FIGS. 10-13, both those corresponding to the reserve word lines and the non-reserve word lines. In FIG. 10, the CG lines for the reserve word lines run in the region 1050 above and below the CG lines for the standard, or non-reserve, word lines that run through the region 1000. In the embodiment of FIG. 11, the CG lines for the reserve word lines run in the region 1150 above, between, and below the CG lines for the standard, or non-reserve, word line that run through the regions 1100. In the embodiment of FIG. 12, the CG lines for the reserve word lines run in the regions 1260 and 1270 above, between, and below the CG lines for the standard, or non-reserve, word lines that run through the regions 1200. Although step 1401 is here listed before, typically these control gate supply lines are formed over the unselected word line drivers that would have been previously formed in steps 1403 and 1405.

The unselected word line control gat drives are formed in steps 1403 and 1405, where these are typically formed at the same time. In an embodiment such as FIG. 2B, where these would be part of the array drivers along with the selected word line drives, these drives would be part of the control die 211. In embodiments such as FIG. 2A, these could be formed on the memory die 200, these could be part of an embodiment where the control circuitry is formed first, with the array structured subsequently formed over the control circuitry. In any of these embodiments, the drivers for the non-reserve word lines, whose number is fixed, are formed in step 1403. These drivers corresponding to the non-reserve word lines are located in region 1000/1100/1200 in the corresponding embodiments of FIGS. 10-12. In embodiments that also include neighboring unselected word line drivers, these CGA and/or CGB for non-reserve word lines are also formed in step 1403.

The unselected word line control gate drivers for the reserve word lines are formed in step 1403, where the number N of these corresponds to the maximum number of reserve word lines, such as 2 m in the embodiment of FIG. 10, 3 m in the embodiments of FIGS. 11 and 12, and 3(n+m) for FIG. 13. The unselected word line control gate drivers for the reserve word lines are formed in regions 1050, 1150, and 1250/1260/1270 in the respective embodiments of FIGS. 10, 11, and 12. In step 1407, the unselected word line control gate drivers for the reserve word lines are then configured according to the reserve lines that are the array, with the corresponding drivers being enable and the extra drivers for which there are no reserve lines not being used, where these can be configured based upon receiving information that specifies this.

In step 1410, the memory array is received or formed. In an embodiment such as FIG. 2B, the memory array is on a separated die that is either received or formed, while in a single die embodiment the array could be formed over the control circuitry, for example. In a control die/memory die embodiment, the dies are bonded in step 1420.

The presented embodiments can help to avoid large schedule impact on row design if the number of word lines per block are changed in the middle of the design phase. The added reserve word lines will help to have less variation on word line layer dependent cell characteristics.

One embodiment includes a non-volatile storage apparatus, comprising a control circuit configured to connect to an array of non-volatile memory cells having a NAND architecture including a block of NAND strings in which the memory cells are each connected along one of a plurality of word lines, the plurality of word lines including M reserve word lines and a plurality of non-reserve word lines, where M is an integer less than or equal to a positive integer N. The control circuit comprises: a first plurality of unselected word line control gate drivers configured to bias control gates of unselected non-reserve word lines of NAND strings of the block selected for a memory operation; and a second plurality of N unselected word line control gate drivers configurable to bias control gates of up to N unselected reserve word lines of the NAND strings of the block selected for the memory operation. The control circuit is configured to: receive a value for M; and for the received value of M, configure M, but not the other (N-M), of the second plurality of unselected word line control gate drivers to bias the control gates of the M unselected reserve lines.

One embodiment includes a method comprising forming control circuitry for a non-volatile memory circuit, including: forming a plurality of control gate supply lines each connectable to a corresponding word line of a block of non-volatile memory cells having a NAND architecture comprising a plurality of NAND strings, the plurality of word lines comprising M reserve word lines and a plurality of non-reserve word lines, where M is an integer less than or equal to a positive integer N; forming a first plurality of unselected word line control gate drivers connectable to bias the control gate supply lines corresponding to the non-reserve word lines when unselected for a memory operation when the block is selected for the memory operation; forming a second plurality of N unselected word line control gate drivers connectable to bias the control gate supply lines corresponding to up to N reserve word lines when unselected for a memory operation when the block is selected for the memory operation; and configuring M, but not the other (N-M), of the second plurality of unselected word line control gate drivers to bias the control gate supply lines corresponding to the M unselected reserve lines based on a specified value of M.

One embodiment includes a non-volatile storage apparatus, comprising: an array of non-volatile memory cells having a NAND architecture including a block of NAND strings in which the memory cells are each connected along one of a plurality of word lines, the plurality of word lines including M reserve word lines and a plurality of non-reserve word lines, where M is an integer less than or equal to a positive integer N; and a control circuit. The control circuit, comprising: a plurality of control gate supply lines each connectable to a corresponding one of the word line; a first plurality of unselected word line control gate drivers connectable to bias the control gate supply lines corresponding to the non-reserve word lines when unselected for a memory operation when the block is selected for the memory operation; and a second plurality of N unselected word line control gate drivers connectable to bias the control gate supply lines corresponding to up to N reserve word lines when unselected for a memory operation when the block is selected for the memory operation, where the control circuit configured to configure M, but not the other (N-M), of the second plurality of unselected word line control gate drivers to bias the control gates of the M unselected reserve lines in response to a specified value of M.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A non-volatile memory apparatus, comprising:
a control circuit configured to connect to an array of non-volatile memory cells having a NAND architecture including a block of NAND strings in which the memory cells are each connected along one of a plurality of word lines, the plurality of word lines including M reserve word lines and a plurality of non-reserve word lines, where M is an integer less than or equal to a positive integer N, the control circuit comprising:
a first plurality of unselected word line control gate drivers configured to bias control gates of unselected non-reserve word lines of NAND strings of the block selected for a memory operation; and
a second plurality of N unselected word line control gate drivers configurable to bias control gates of up to N unselected reserve word lines of the NAND strings of the block selected for the memory operation,
the control circuit configured to:
receive a value for M; and
for the received value of M, configure M, but not the other (N-M), of the second plurality of unselected word line control gate drivers to bias the control gates of the M unselected reserve lines.

2. The non-volatile memory apparatus of claim 1, wherein at least a portion of the control circuit is formed on a control die, the non-volatile memory apparatus further comprising:
a memory die including the array of non-volatile memory cells, the memory die separate from and bonded to the control die.

3. The non-volatile memory apparatus of claim 1, the control circuit further configured to:
receive an updated value for M; and
for the updated value of M, reconfigure configure M, but not the other (N-M), of the second plurality of unselected word line control gate drivers to bias the control gates of the M unselected reserve lines.

4. The non-volatile memory apparatus of claim 1, the control circuit further comprising:
a third plurality of unselected word line control gate drivers configured to bias control gates of unselected non-reserve word lines of NAND strings of the block selected for a memory operation that neighbor a word line selected for the memory operation at a different bias level than that at which the first plurality of unselected word line control gate drivers bias others of the non-reserve word lines.

5. The non-volatile memory apparatus of claim 4, wherein the third plurality of unselected word line control gate drivers are configured to bias neighboring unselected word lines on a first side the select word line at a different bias level than neighboring unselected word lines on a second side the select word line.

6. The non-volatile memory apparatus of claim 4, the control circuit further comprising:
a fourth plurality of N unselected word line control gate drivers configurable to bias control gates of up to N unselected reserve word lines of the NAND strings of the block selected for the memory operation that neighbor a word line selected for the memory operation at a different bias level than that at which the second plurality of unselected word line control gate drivers bias others of the reserve word lines, the control circuit further configured to:
for the received value of M, configure M, but not the other (N-M), of the third plurality of unselected word line control gate drivers to bias the control gates of the M unselected neighboring reserve lines.

7. The non-volatile memory apparatus of claim 1, further comprising:
the array of non-volatile memory cells, wherein each of the NAND strings of the block are connected between a source line and a corresponding bit line, and wherein one or more of the reserve word lines are located on the NAND strings between the non-reserve word lines and one of either the source line or the corresponding bit lines.

8. The non-volatile memory apparatus of claim 7, wherein one or more of the reserve word lines are located on the NAND strings between the non-reserve word lines and another of either the source line or the corresponding bit lines.

9. The non-volatile memory apparatus of claim 1, further comprising:
the array of non-volatile memory cells, wherein one or more of the reserve word lines are located on the NAND strings between a first subset of the non-reserve word lines and a second subset of the non-reserve word lines.

10. The non-volatile memory apparatus of claim 1, further comprising:
the array of non-volatile memory cells, wherein the array has a three-dimensional structure in which the NAND strings extend vertically from a horizontal substrate.

11. A method, comprising:
forming control circuitry for a non-volatile memory circuit, including:
forming a plurality of control gate supply lines each connectable to a corresponding word line of a block of non-volatile memory cells having a NAND architecture comprising a plurality of NAND strings, the plurality of word lines comprising M reserve word lines and a plurality of non-reserve word lines, where Mis an integer less than or equal to a positive integer N;
forming a first plurality of unselected word line control gate drivers connectable to bias the control gate supply lines corresponding to the non-reserve word lines when unselected for a memory operation when the block is selected for the memory operation;
forming a second plurality of N unselected word line control gate drivers connectable to bias the control gate supply lines corresponding to up to N reserve word lines when unselected for a memory operation when the block is selected for the memory operation; and
configuring M, but not the other (N-M), of the second plurality of unselected word line control gate drivers to bias the control gate supply lines corresponding to the M unselected reserve lines based on a specified value of M.

12. The method of claim 11, wherein a value of M for the second plurality of unselected word line control gate drivers is reconfigurable.

13. The method of claim 11, further comprising:
forming a non-volatile memory array including the block of non-volatile memory cells having a NAND architecture comprising a plurality of NAND strings, wherein each of the NAND strings of the block are connected between a source line and a corresponding bit line, and wherein one or more of the reserve word lines are located on the NAND strings between the non-reserve word lines and one of either the source line or the corresponding bit lines.

14. The method of claim 13, wherein one or more of the reserve word lines are located on the NAND strings between the non-reserve word lines and another of either the source line or the corresponding bit lines.

15. The method of claim 11, further comprising:
forming a non-volatile memory array including the block of non-volatile memory cells having a NAND architecture, wherein one or more of the reserve word lines are located on the NAND strings between a first subset of the non-reserve word lines and a second subset of the non-reserve word lines.

16. The method of claim 11, further comprising:
forming a non-volatile memory array including the block of non-volatile memory cells having a NAND architecture, wherein the array has a three-dimensional structure in which the NAND strings extend vertically from a horizontal substrate.

17. The method of claim 11, wherein at least a portion of the control circuitry is formed on a control die, the method further comprising:
forming a non-volatile memory array including the block of non-volatile memory cells having a NAND architecture on a memory die; and
bonding the control die to the memory die.

18. The method of claim 11, further comprising:
forming the control circuitry on a die; and
forming a non-volatile memory array including the block of non-volatile memory cells having a NAND architecture on the die over the control circuitry.

19. The method of claim 11, wherein the control gate supply lines run perpendicularly to the word lines.

20. A non-volatile memory apparatus, comprising:
an array of non-volatile memory cells having a NAND architecture including a block of NAND strings in which the memory cells are each connected along one of a plurality of word lines, the plurality of word lines including M reserve word lines and a plurality of non-reserve word lines, where M is an integer less than or equal to a positive integer N; and
a control circuit, comprising:
a plurality of control gate supply lines each connectable to a corresponding one of the word lines;
a first plurality of unselected word line control gate drivers connectable to bias the control gate supply lines corresponding to the non-reserve word lines when unselected for a memory operation when the block is selected for the memory operation; and
a second plurality of N unselected word line control gate drivers connectable to bias the control gate supply lines corresponding to up to N reserve word lines when unselected for a memory operation when the block is selected for the memory operation,
the control circuit configured to:
configure M, but not the other (N-M), of the second plurality of unselected word line control gate drivers to bias the control gates of the M unselected reserve lines in response to a specified value of M.
